(19) United States
(12) Patent Application Publication
(10) Pub. No.: US 2025/0087285 A1
(43) Pub. Date: Mar. 13, 2025

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventor: Meng-Sheng CHANG, Hsinchu County (TW)

(73) Assignee: TAIWAN SEMICONDUCTOR MANUFACTURING COMPANY, LTD., Hsinchu (TW)

(21) Appl. No.: 18/465,815

(22) Filed: Sep. 12, 2023

(51) Int. Cl. G11C 17/16; G11C 17/18; H01L 21/8238; H01L 27/092; H01L 29/06; H01L 29/66; H01L 29/78; H01L 29/786; H10B 20/25

(52) U.S. Cl. CPC G11C 17/16; G11C 17/18; H10B 20/25; H10D 30/024; H10D 30/62; H10D 30/6757; H10D 62/118; H10D 84/0186; H10D 84/0193; H10D 84/038; H10D 84/853

(57) ABSTRACT

A method includes forming a first gate structure across a first active region on a substrate within a memory region, wherein the first gate structure is of a first transistor being of a first conductivity type; forming a second gate structure across a second active region on the substrate within a peripheral region, wherein the second gate structure is of a second transistor being of a second conductivity type, the second conductivity type is opposite to the first conductivity type; forming a first gate contact over the first gate structure, the first gate contact overlapping with the first active region; forming a second gate contact over the second gate structure, the second gate contact non-overlapping with the second active region.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic top view of a memory system including a semiconductor structure in accordance with some embodiments of the present disclosure.

FIG. 1B shows a diagram of a threshold voltage characteristic of an n-channel metal-oxide-semiconductor (NMOS) transistor, considering varying gate contact locations on the transistor's gate structure in accordance with some embodiments of the present disclosure.

FIG. 1C shows a schematic diagram of a threshold voltage characteristic of a p-channel metal-oxide-semiconductor (PMOS) transistor, considering varying gate contact locations on the transistor's gate structure in accordance with some embodiments of the present disclosure.

FIG. 1D illustrates a circuit diagram of an electronic fuse (efuse) memory cell in accordance with some embodiments of the present disclosure.

FIGS. 1E, 1H, and 1K illustrate perspective views of an example fin-like field-effect transistor (FinFET) device, an nano-FET device, and a thin film transistor (TFT) device, respectively, in accordance with some embodiments of the present disclosure.

FIGS. 1F and 1G illustrate cross-sectional views of the semiconductor structure obtained from reference cross-section A-A′, B-B′, C-C′, D-D′, E-E′, and F-F′ in FIG. 1A in accordance with some embodiments of the present disclosure.

FIGS. 1I and 1L illustrate cross-sectional views of semiconductor structures, with an nano-FET device and a TFT device, corresponding to FIG. 1E in accordance with some embodiments of the present disclosure.

FIGS. 1J and 1M illustrate cross-sectional views of semiconductor structures corresponding to FIG. 1F, with an nano-FET device and a TFT device, in accordance with some embodiments of the present disclosure.

FIGS. 1N, 1P, and 1R illustrate cross-sectional views of semiconductor structures in accordance with some embodiments of the present disclosure.

FIGS. 1O and 1Q illustrate local enlarged views of semiconductor structures corresponding to regions C7 and C8 in FIGS. 1N and 1P in accordance with some embodiments of the present disclosure.

FIGS. 2A-7B illustrate cross-sectional views of intermediate stages in the formation of a semiconductor structure in accordance with some embodiments of the present disclosure.

FIG. 8A illustrates a circuit diagram of an anti-fuse memory cell in accordance with some embodiments of the present disclosure.

FIGS. 8B-10 illustrate different views of bit-cells in memory arrays accordance with some embodiments of the present disclosure.

FIGS. 11A-14 illustrate different views of semiconductor structures in peripheral regions of memory systems in accordance with some embodiments of the present disclosure.

FIG. 15 is a schematic diagram of an electronic design automation (EDA) system in accordance with some embodiments of the present disclosure.

FIG. 16 is a block diagram of an IC manufacturing system and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present disclosure are directed to, but not otherwise limited to, a fin-like field-effect transistor (FinFET) device. The FinFET device, for example, may be a complementary metal-oxide-semiconductor (CMOS) device including a P-type metal-oxide-semiconductor (PMOS) FinFET device and an N-type metal-oxide-semiconductor (NMOS) FinFET device. The following disclosure will continue with one or more FinFET examples to illustrate various embodiments of the present disclosure. It is understood, however, that the application should not be limited to a particular type of device, except as specifically claimed.

The fins may be patterned by any suitable method. For example, the fins may be patterned using one or more photolithography processes, including double-patterning or multi-patterning processes. The double-patterning or the multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

Throughout the evolution of integrated circuits (ICs), devices incorporated within N/PMOS memory cell region or peripheral region may employ the same gate contact (VG) placement strategy. This consistent positioning of the gate contact across the different devices of a memory system (e.g., electronic fuse (eFuse)) may lead to a lack of design flexibility. Each device in the memory system may have unique operational requirements that may not align with a uniform gate contact positioning strategy. This could limit the layout designer's ability to balance the device performance effectively, such as power efficiency, read/write speeds, and data retention.

Therefore, the present disclosure in various embodiments provides a flexibility of gate contact (VG) placement within a memory bit-cell and some peripheral devices. For example, in the NMOS memory cell, the gate contact can be positioned inside the active region from the top view. Alternatively, this disclosure can allow for the implementation of a three-dimensional (3D) stack of indium gallium zinc oxide (IGZO) thin film transistor (TFT) devices. This configuration can provide an increased threshold voltage shift, enabling a boost in the cell current or a reduction in cell leakage. In addition, for the peripheral sense amplifier (e.g., including PMOS transistor), the gate contact can be positioned inside the active region from the top view. This configuration can provide a reduced threshold voltage shift, thus expanding the read window and enhancing the sense amplifier's performance. Furthermore, for power header (e.g., including PMOS/NMOS transistor), the gate contact can be positioned outside the active region from the top view. This configuration can provide stability in the threshold voltage, thus contributing to efficient power utilization within the memory system.

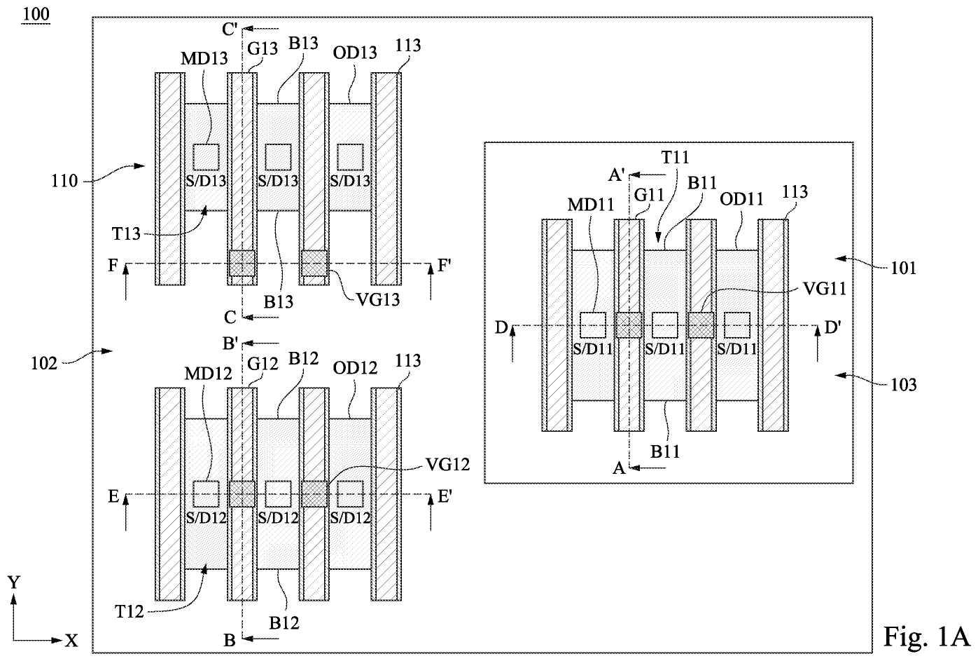

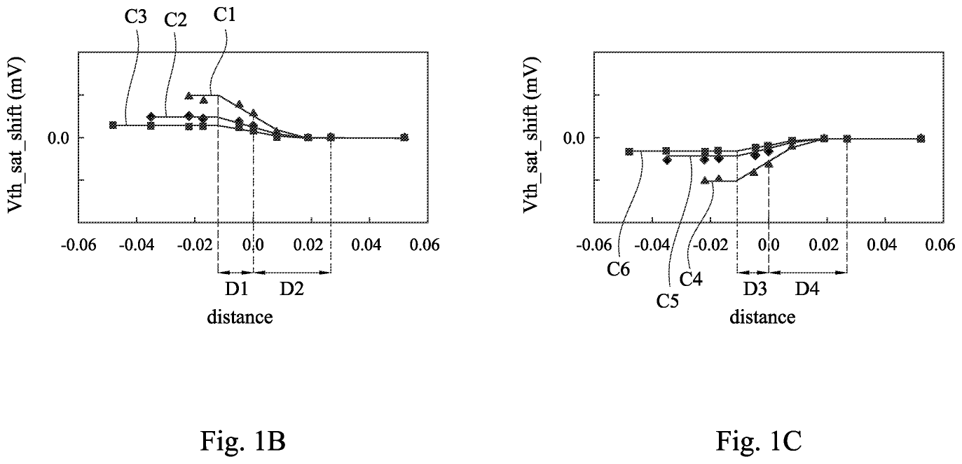

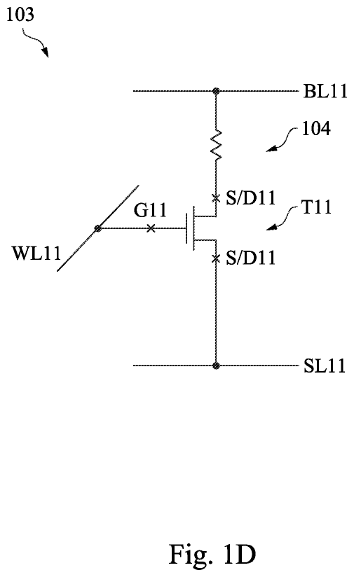

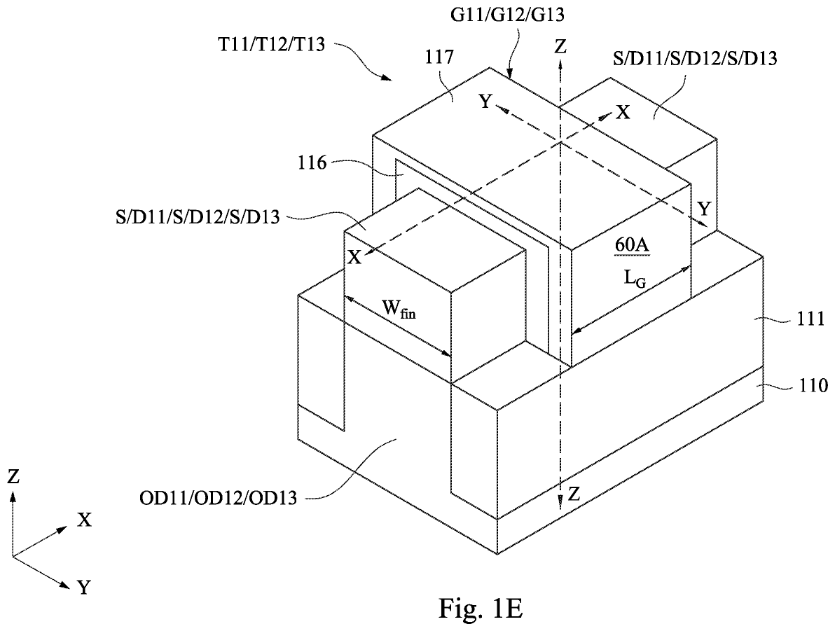

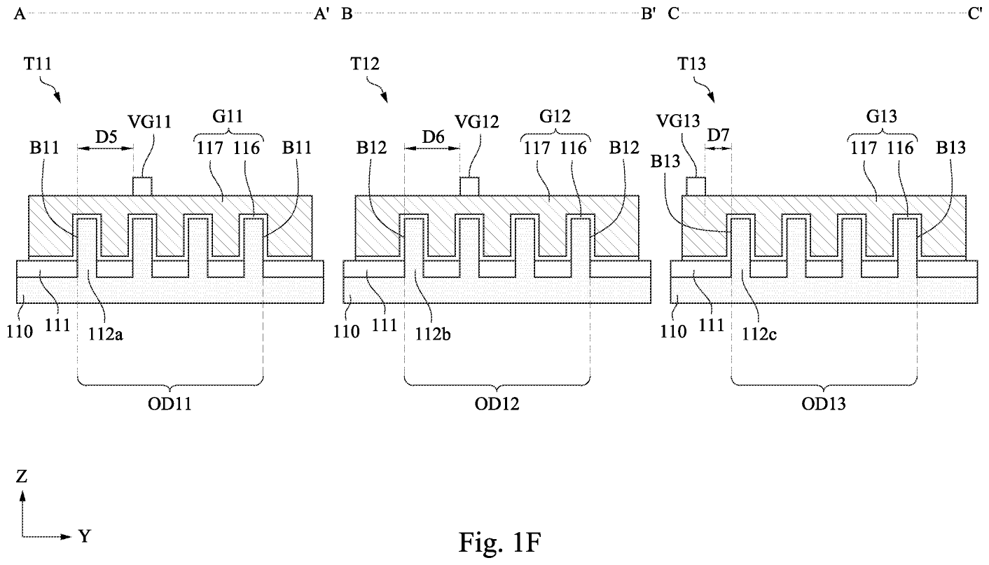

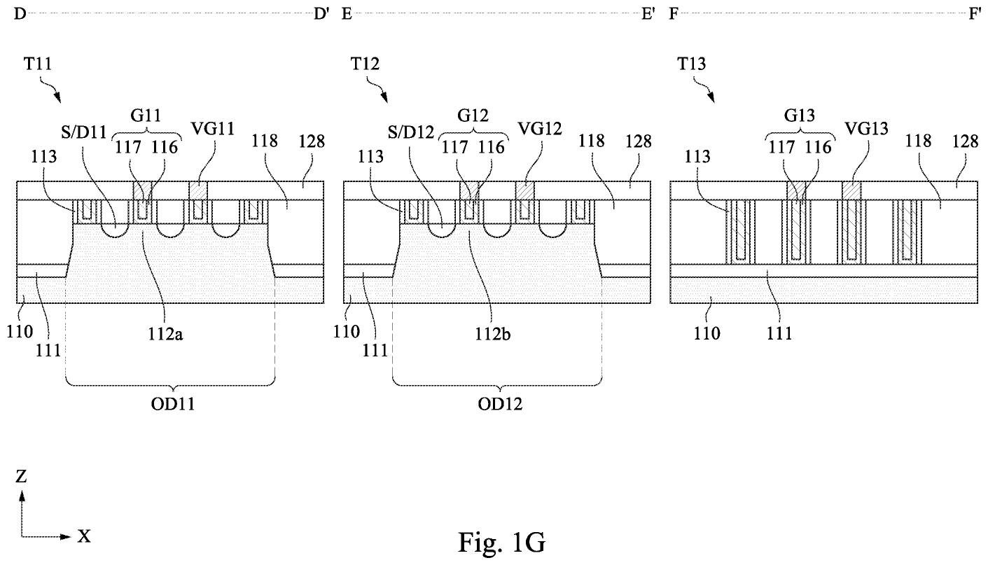

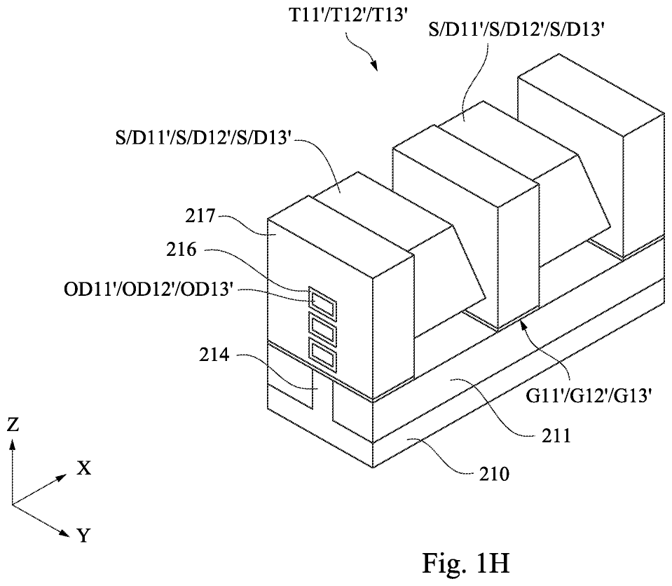

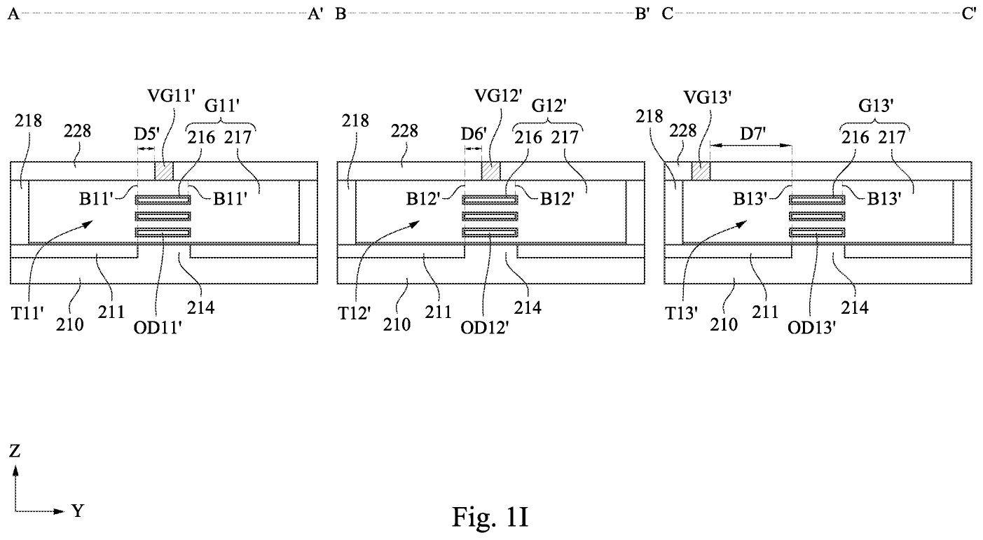

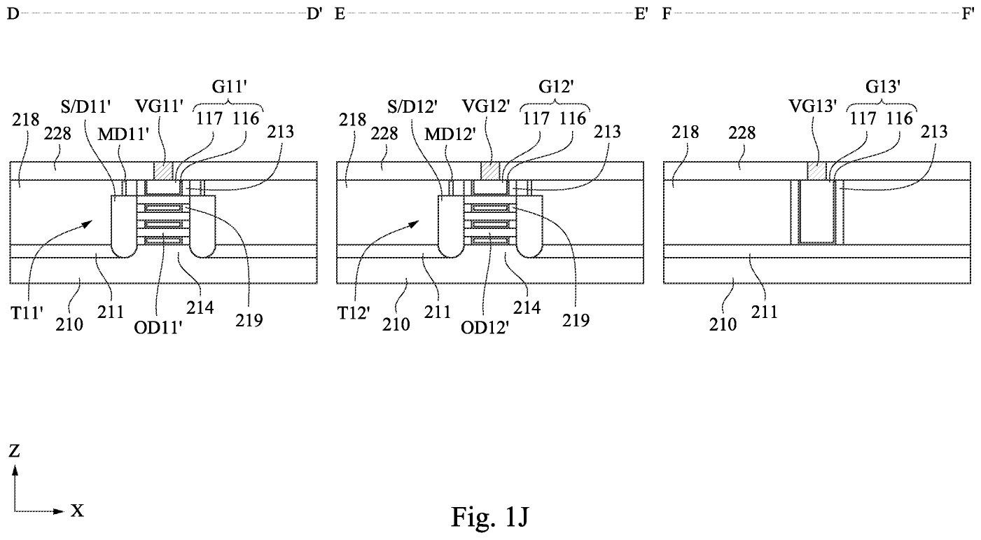

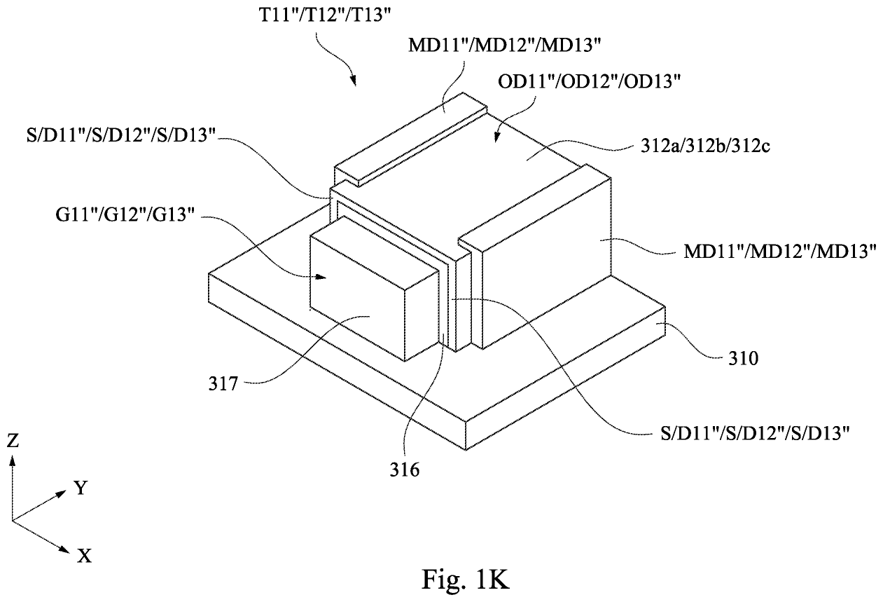

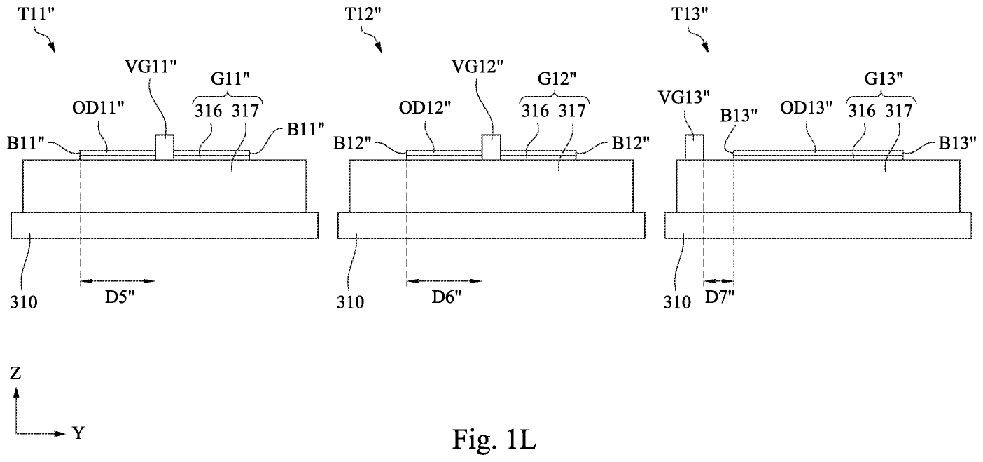

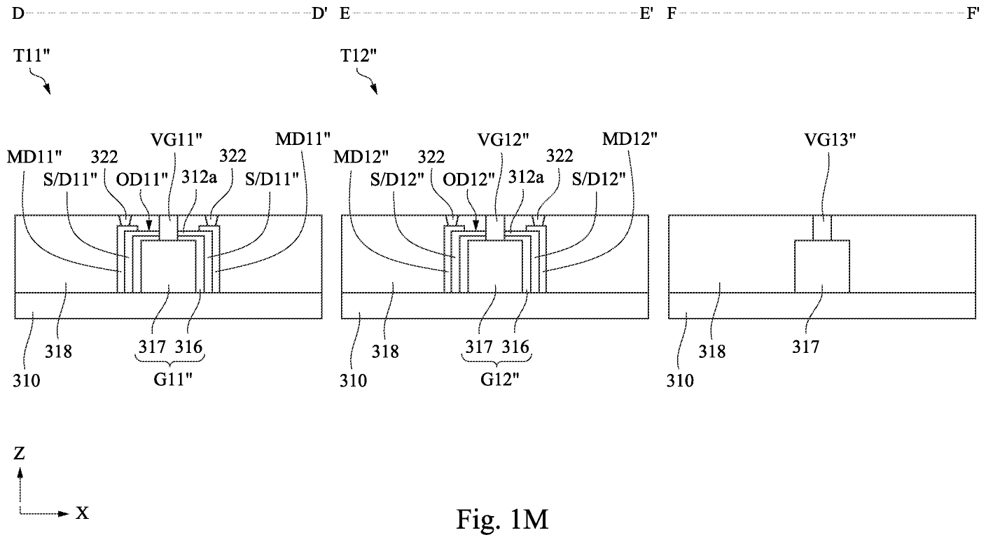

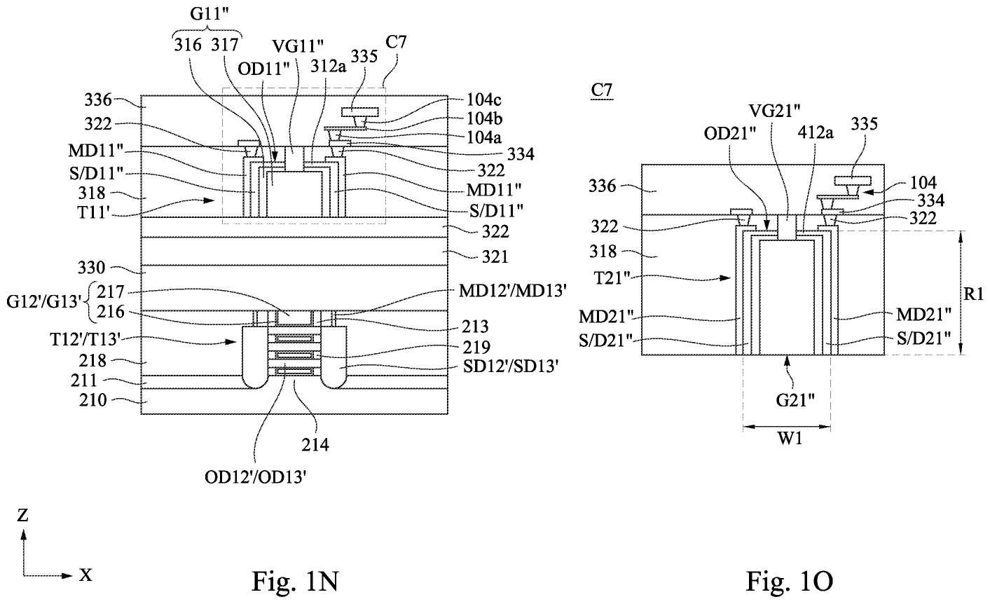

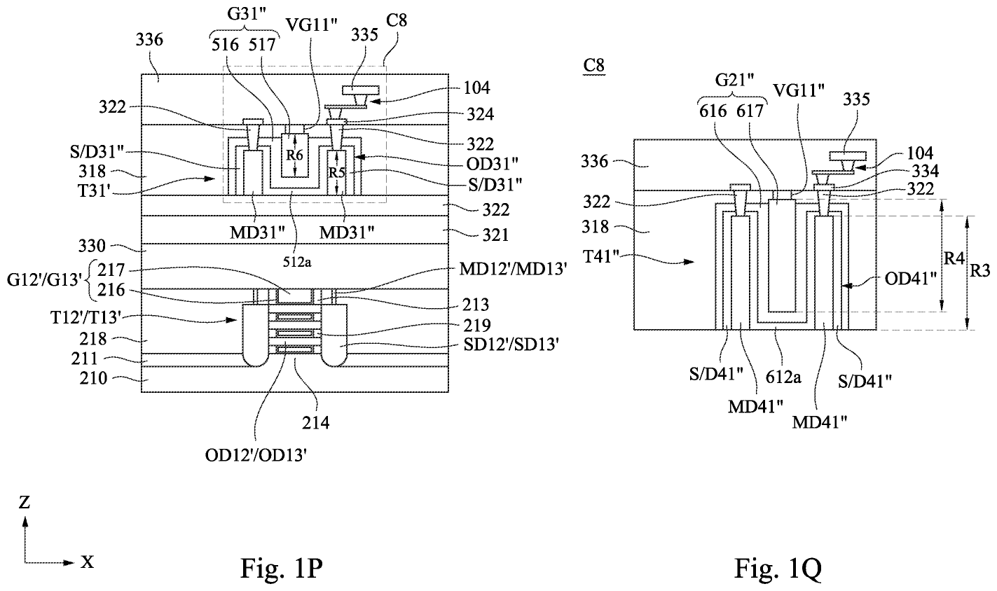

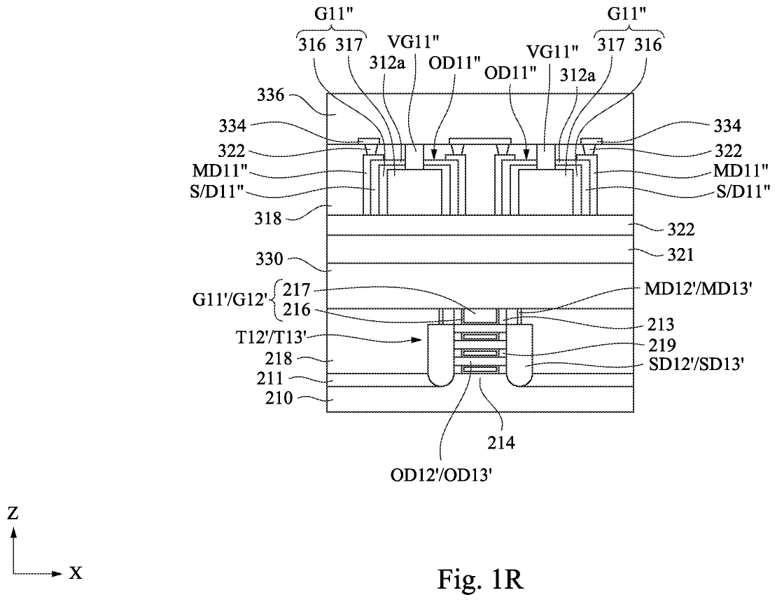

Reference is made to FIG. 1A. FIG. 1A illustrates a schematic top view of a memory system 100 including semiconductor structures in accordance with some embodiments of the present disclosure. A memory array region 101 and a peripheral circuit region 102 for accessing one or more portions of the memory array region 101 can be provided in the memory system 100. The peripheral circuit region 102 includes devices for reading from and/or writing to one or more portions of the memory array region 101. In some embodiments, the peripheral circuit region 102 may include sense amplifiers, power headers for providing power to the various units in the peripheral circuit region 102, a write driver circuitry connected to bit-lines for writing data into a bit-cell 103 of the memory array region 101, a write logic, a write assist circuit, a built-in self-test (BIST)/data input circuitry, a pre-charge/equalization circuit coupled to the bitlines, a read column multiplexer, a pre-charge/equalization circuit coupled to data lines of the bit-cell 103 of the memory array region 101, a data output circuitry, and a column redundancy circuit. Other structures and configurations of the peripheral circuit region 102 are within the scope of the present disclosure. As shown in FIG. 1A, the memory system 100 may include at least one transistor T11 in the bit-cell 103 of the memory array region 101 and at least one transistor T12 and at least one transistor T13 in the peripheral circuit region 102. In some embodiments, the bit-cells 103 may include, but are not limited to, an eFuse memory cell, an anti-fuse memory cell, magnetoresistive random-access memory (MRAM) cell, the like, or combinations thereof. In some embodiments, the transistor T12 may be of a sense amplifier and can be interchangeably referred to as a sense amplifier transistor, and the transistor T13 may be of a power header and can be interchangeably referred to as a power header transistor.

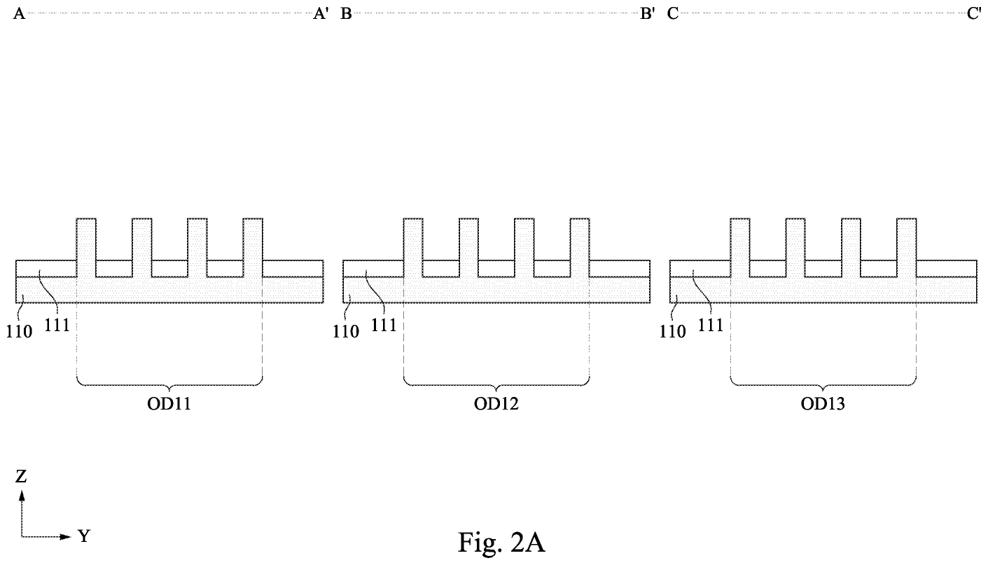

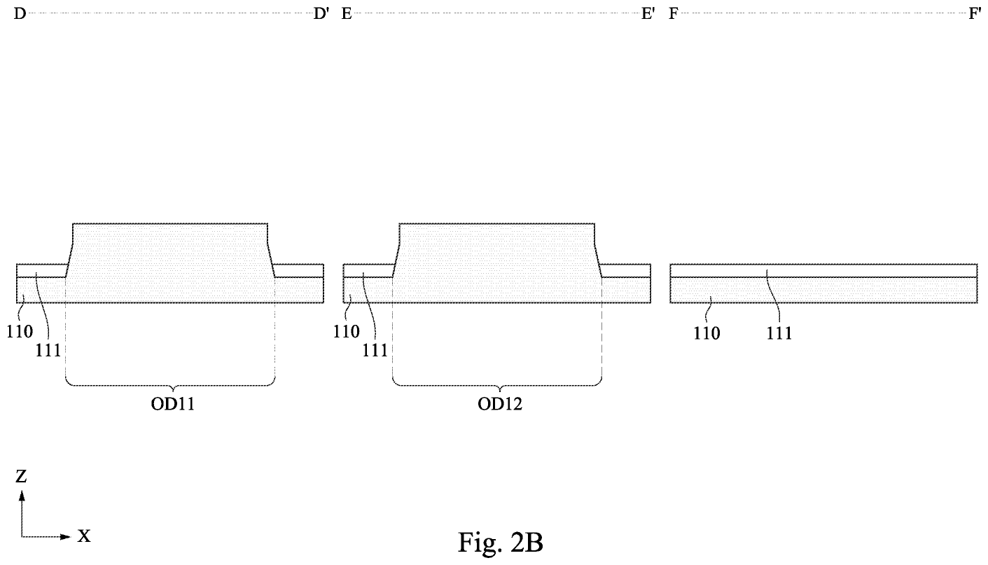

In some embodiments, the memory array region 101 can be formed at a same level height as the peripheral circuit region 102 (see FIGS. 2A-7B), such that the peripheral logic region 102 may laterally surround the memory array region 101, and the transistors in the peripheral circuit region 102 can be at a same level height as transistors in the memory array region 101. In some embodiments, the memory array region 101 can be formed at a different level height than the peripheral circuit region 102 (see FIGS. 1N-1R), such that the peripheral circuit region 102 can be distributed in the same device area as (i.e., same footprint) the memory array region 101, and transistors in the peripheral circuit region 102 may overlap with transistors in the memory array region 101. By way of example and not limitation, the memory array region 101 can be at a higher level height than the peripheral circuit region 102 (see FIGS. 1N-1R). In some embodiments, the memory array region 101 can be at a lower level height than the peripheral circuit region 102.

In some embodiments, the transistor T11, T12, and/or T13 may include an n-type transistor and/or a p-type transistor, but embodiments are not limited thereto. The transistor T11, T12, and/or T13 can be any suitable type of transistor including, but not limited to, metal oxide semiconductor field effect transistors (MOSFET), complementary metal oxide semiconductors (CMOS) transistors, p-channel metal-oxide semiconductors (PMOS), N-channel metal-oxide semiconductors (NMOS), bipolar junction transistors (BJT), high voltage transistors, high frequency transistors, p-channel and/or N-channel field effect transistors (PFETs/NFETs), FinFETs, planar MOS transistors with raised source/drains, nanosheet FETs, nanowire FETs, film transistors (TFTs), or the like.

In the memory system 100, adjusting the threshold voltages of various circuits or transistors within bit-cells 103 can enhance the system's overall performance. These optimizations are reliant on the role of the transistor within the memory system 100. For example, a higher threshold voltage for the transistor T11 within a bit-cell 103 can reduce leakage currents. This reduced leakage effectively minimizes unwanted energy dissipation and improves data retention, enhancing the operational efficiency of the memory system. On the other hand, transistor T12 within the peripheral sense amplifier can be improved from a lower threshold voltage. A lower threshold voltage can increase the speed at which the transistor T12 switches, resulting in a broader read window. This optimization can accelerate the read operations and enhance the overall read performance of the memory system 100. Moreover, in the peripheral power headers, the transistor T13 devoid of threshold voltage shifts can lead to more energy-efficient operation. A stable threshold voltage reduces the risk of unexpected power spikes, allowing the system to maintain a relatively low and consistent power consumption. To capitalize on these features, it can design suitable threshold voltages for transistors located in different regions within memory system 100. This optimization may involve controlling the relationship between the gate contacts VG11, VG12, and VG13 and its position on the transistor's active region (e.g., active regions OD11, OD12, and OD13), which in turn governs the transistor's threshold voltage. By adjusting this positional relationship, the threshold voltages of transistors across various regions can be adjusted. In some embodiments, the active region can be interchangeably referred to as an oxide definition (OD). Other embodiments may contain more or fewer active regions. In some embodiments, the number of active region OD11 OD12, or OD13 can be between about 1 to about 10, such as about 1, 2, 3, 4, 5, 6, 7, 8, 9, or 10.

Additionally, the impact of gate contact positioning on threshold voltage may vary depending on the type of transistor. For example, n-channel metal-oxide-semiconductor (NMOS) and p-channel metal-oxide-semiconductor (PMOS) transistors may respond differently to the same gate contact and gate structure positioning due to their inherently different operational characteristics, and these characteristics will be explained in the following description.

Reference is made to FIGS. 1B and 1C. FIG. 1B shows a diagram of a threshold voltage characteristic of an n-channel metal-oxide-semiconductor (NMOS) transistor, considering varying gate contact locations on the transistor's gate structure, in which curves C1, C2, C3 represent a transistor with 2, 4, and 6 active regions (e.g., active regions OD11, OD12, or OD13 as shown in FIG. 1A), respectively, in accordance with some embodiments of the present disclosure. FIG. 1C shows a schematic diagram of a threshold voltage characteristic of a p-channel metal-oxide-semiconductor (PMOS) transistor, considering varying gate contact locations on the transistor's gate structure, in which curves C4, C5, C6 represent a transistor with 2, 4, and 6 active regions (e.g., active regions OD11, OD12, or OD13 as shown in FIG. 1A), respectively, in accordance with some embodiments of the present disclosure. In some embodiments, active regions OD11, OD12, and OD13 as shown in FIG. 1A can be formed over a substrate 110 and extend along the X-direction within the memory array region 101 and the peripheral circuit region 102. The transistor T11, T12, and T13 can be formed on the active regions OD11, OD12, and OD13.

As illustrated in FIG. 1B, for NMOS transistors, patterns can be observed related to the positioning of the gate contact (e.g., gate contacts VG11, VG12, and VG13 as shown in FIG. 1A) and its impact on the NMOS transistor's threshold voltage. When the gate contact overlaps with the active region and is moved further from an active region edge, the threshold voltage of the NMOS transistor tends to be increased. In some embodiments, the active region edge (e.g. active region edges B11, B12, and B13 of the active regions OD11, OD12, and OD13 as shown in FIG. 1A) can extend along a direction perpendicular to a lengthwise direction of the gate structures G11. Beyond a distance D1, this threshold voltage achieves stability, indicating that the NMOS transistor has reached its operating condition for this configuration. In contrast, when the gate contact is positioned outside the active region and distanced further from the active region edge, the NMOS transistor exhibits a tendency towards a stable threshold voltage devoid of shifts. After reaching a distance D2, the threshold voltage maintains a stable value, suggesting that the NMOS transistor is less sensitive to additional changes in the gate contact positioning beyond this distance. The depicted trends of curves C1, C2, and C3 in FIG. 1B represent these characteristics. The curves C1, C2, and C3 can provide the relationship between gate contact location and threshold voltage for NMOS transistor with different numbers of active regions, illustrating how control of the gate contact positioning can optimize NMOS transistor performance. In some embodiments, the distance D1 may be greater than about 5 nm, such as about 5, 6, 7, 8, 9, 10, 11, 12, 13, 14, or 15 nm. In some embodiments, the distance D2 may be greater than about 15 nm, such as about 15, 16, 17, 18, 19, 20, 21, 22, 23, 24, or 25 nm.

Furthermore, the curves C1, C2, and C3 in FIG. 1B can indicate that a quantity of active regions plays a role in determining the degree of impact the gate contact position has on the threshold voltage. The NMOS transistors with fewer active regions appear to exhibit greater sensitivity to changes in gate contact positioning. For example, when the gate contact overlaps with the active region, the NMOS transistor having two active regions can achieve a higher threshold voltage compared to the NMOS transistor configured with four active regions. Similarly, when the gate contact overlaps with the active region, the NMOS transistor having four active regions can achieve a higher threshold voltage compared to the NMOS transistor configured with six active regions. This pattern suggests an inverse relationship between the number of active regions and the attainable threshold voltage for a given gate contact position.

As illustrated in FIG. 1C, for PMOS transistors, patterns can be observed related to the positioning of the gate contact (e.g., gate contacts VG11, VG12, and VG13 as shown in FIG. 1A) and its impact on the PMOS transistor's threshold voltage. When the gate contact overlaps with the active region and is moved further from an active region edge of the active region, the threshold voltage of the PMOS transistor tends to be decreased. Beyond a distance D3, this threshold voltage achieves stability, indicating that the PMOS transistor has reached its operating condition for this configuration. In contrast, when the gate contact is positioned outside the active region and distanced further from the active region edge, the PMOS transistor exhibits a tendency towards a stable threshold voltage devoid of shifts. After reaching a distance D4, the threshold voltage maintains a stable value, suggesting that the PMOS transistor is less sensitive to additional changes in the gate contact positioning beyond this distance. The depicted trends of curves C4, C5, and C6 in FIG. 1C represent these characteristics. The curves C4, C5, and C6 can provide the relationship between gate contact location and threshold voltage for PMOS transistor with different numbers of active regions, illustrating how control of the gate contact positioning can optimize PMOS transistor performance. In some embodiments, the distance D3 may be greater than about 5 nm, such as about 5, 6, 7, 8, 9, 10, 11, 12, 13, 14, or 15 nm. In some embodiments, the distance D4 may be greater than about 15 nm, such as about 15, 16, 17, 18, 19, 20, 21, 22, 23, 24, or 25 nm.

Furthermore, the curves C4, C5, and C6 in FIG. 1C can indicate that a quantity of active regions plays a role in determining the degree of impact the gate contact position has on the threshold voltage. The PMOS transistors with fewer active regions appear to exhibit greater sensitivity to changes in gate contact positioning. For example, when the gate contact overlaps with the active region, the PMOS transistor having two active regions can achieve a lower threshold voltage compared to the PMOS transistor configured with four active regions. Similarly, when the gate contact overlaps with the active region, the PMOS transistor having four active regions can achieve a lower threshold voltage compared to the PMOS transistor configured with six active regions. This pattern suggests an inverse relationship between the number of active regions and the attainable threshold voltage for a given gate contact position.

Reference is made to FIGS. 1A-1C. In the memory array region 101's bit-cell 103 as shown in FIG. 1A, a minimize leakage in the memory system 100 can be achieved by enhancing the threshold voltage of transistor T11. Therefore, the transistor T11 can employ an NMOS transistor, with the gate contacts VG11 overlapping with the active region OD11 of the transistor T11. This configuration can increase the threshold voltage, hence reducing the current leakage.

In addition, for the sense amplifier within the peripheral circuit region 102 as shown in FIG. 1A, an improved read window can be achieved by reduction of the threshold voltage of the transistor T12 as the sense amplifier. Therefore, the transistor T12 can employ a PMOS transistor, with the gate contacts VG12 overlapping with the active region OD12 of the transistor T12. This configuration can reduce the threshold voltage, thus expanding the read window and enhancing the sense amplifier's performance.

Moreover, for the power header within the peripheral circuit region 102 as shown in FIG. 1A, an efficient power utilization can be achieved by stability in the threshold voltage of the transistor T13 as the power header. Therefore, the transistor T13 can employ a NMOS transistor or a PMOS transistor, with the gate contacts VG13 non-overlapping with the active region OD13 of the transistor T13. This configuration can maintain a stable threshold voltage for the transistor T13, devoid of threshold voltage shifts, which contributes to an efficient power utilization within the memory system 100.

Reference is made to FIGS. 1D-1R. FIG. 1D illustrates a circuit diagram of the bit-cell 103 (e.g., eFuse memory cell) of a one-time programmable (OTP) memory device within the memory array region 101 (see FIG. 1A) in accordance with some embodiments of the present disclosure, in which the OTP memory device may include one-transistor and one-resistor (1T1R) configuration. FIGS. 1E-1R illustrate schematic views of a FinFET device, an nano-FET device, and a thin film transistor (TFT) device in accordance with some embodiments of the present disclosure. Specifically, FIGS. 1E, 1H, and 1K illustrate perspective view of the FinFET device, the nano-FET device, and the TFT device, respectively, in accordance with some embodiments of the present disclosure. FIGS. 1F, 1G, 1I, 1L, 1J, 1M, and 1N-1R illustrate cross-sectional views of the corresponding FinFET device, nano-FET device, and/or TFT device in accordance with some embodiments of the present disclosure.

In some embodiments, the transistors in the peripheral circuit region 102 (see FIG. 1A) can be of a same device type as the transistors in the memory array region 101 (see FIG. 1A), such as FinFET device, GAA device, TFT device, or other suitable devices as shown in FIGS. 1F, 1G, 1I, 1J, 1L, and 1M. By way of example and not limitation, as shown in FIGS. 1F and 1G, transistors in both the peripheral circuit region 102 and the memory array region 101 can be of the FinFET device. As shown in FIGS. 1I and 1J, the transistors both in the memory array region 101 and in the peripheral circuit region 102 can be of the nano-FET device. As shown in FIGS. 1L and 1M, the transistors both in the memory array region 101 and in the peripheral circuit region 102 can be of the TFT device. As shown in FIGS. 1N-1R, the transistors in the peripheral circuit region 102 can be of a different device type than the transistors in the memory array region 101. By way of example and not limitation, transistors in the peripheral circuit region 102 can be of GAA device, and transistors in the memory array region 101 can be of TFT device.

Reference is made to FIGS. 1D-1G. FIGS. 1F and 1G illustrate cross-sectional views of the semiconductor structure obtained from reference cross-section A-A′, B-B′, C-C′, D-D′, E-E′, and F-F′ in FIG. 1A in accordance with some embodiments of the present disclosure. Specifically, at least one of the transistors (e.g. transistors T11, T12, and T13 as shown in FIG. 1A) in the memory system 100 can employ a FinFET device (see in FIG. 1E). The FinFET device can be a non-planar multi-gate transistor that is built over the substrate 110, for example a silicon substrate. The substrate 110 may be made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide InGaAs, indium arsenide, indium phosphide, indium antimonide, gallium arsenic phosphide, or gallium indium phosphide), or the like. Further, the substrate 110 may include an epitaxial layer (epi-layer), which may be strained for performance enhancement, and/or may include a silicon-on-insulator (SOI) structure. An N-type well and a P-type well are formed in the substrate 110. A P-type FinFET is formed over the N-type well, and an N-type FinFET is formed over the P-type well.

Specifically, thin silicon-containing “fin-like” structures (hereinafter referred to as a “fin”) forms the active regions OD11, OD12, and OD13 of the transistors T11, T12, and T13. The fin-like structure extends along an X-direction and protrudes upwardly out of the dielectric isolation structure 111 as shown in FIG. 1E. The fin-like structure has a fin width W_{fin} measured along a Y-direction that is orthogonal to the X-direction. The active regions OD11, OD12, and OD13 each can be bordered by a first outer edge B11, B12, or B13 of a first outermost one of the fin-like structures and a second outer edge B11, B12, or B13 of a second outermost one of the fin-like structures opposite to the first outer edge B11, B12, or B13 from a top view. A portion of the fin-like structure being wrapped around by gate structures G11, G12, and G13 can serve as the channel regions 112a. 112b, and 112c (see FIGS. 1F and 1G) of the FinFET devices. The effective channel length of the FinFET device is determined by the dimensions of the fin-like structure. In some embodiments, the channel regions 112a, 112b, and 112c can be interchangeably referred to as channel patterns, fin structures, or fin patterns. As shown in FIGS. 1E-1G, the transistor T11 can include the channel region 112a, the source/drain regions S/D11 on opposite sides of the channel region 112a and connected to the channel region 112a, and the gate structure G11 wrapping around the channel region 112a. The transistor T12 can include the channel region 112b, the source/drain regions S/D12 on opposite sides of the channel region 112a and connected to the channel region 112b, and the gate structure G12 wrapping around the channel region 112b. The transistor T13 can include the channel region 112c, the source/drain regions S/D13 on opposite sides of the channel region 112c and connected to the channel region 112c, and the gate structures G13 wrapping around the channel region 112c. The transistor T11 can be located in the memory array region 101, and the transistors T12 and T13 can be located in the peripheral circuit region 102.

The integrated circuit structure in the memory system 100 as shown in FIGS. 1E-1G may further include a dielectric isolation structure 111, such as a shallow trench isolation (STI), formed over the N-type well and the P-type well in the substrate 110. The dielectric isolation structure 111 can define and electrically isolate the active regions OD11, OD12, and OD13 of the transistors T11. T12, and T13. Formation of the STI region 111 includes patterning the semiconductor substrate 110 to form one or more trenches in the substrate 110 by using suitable photolithography and etching techniques, depositing one or more dielectric materials (e.g., silicon oxide) to completely fill the trenches in the substrate 110, followed by a planarization process (e.g., chemical mechanical polish (CMP) process) to level the dielectric isolation structure 111 with the active regions OD11, OD12, and OD13. The dielectric materials of the dielectric isolation structure 111 may be deposited using a high density plasma chemical vapor deposition (HDP-CVD), a low-pressure CVD (LPCVD), sub-atmospheric CVD (SACVD), a flowable CVD (FCVD), spin-on coating, and/or the like, or a combination thereof. After the deposition, an anneal process or a curing process may be performed, especially when the dielectric isolation structure 111 is formed using flowable CVD. In some embodiments, the dielectric isolation structure 111 can be further recessed (e.g., by an etch back process) to fall below the top surfaces of the active regions OD11. OD12, and OD13, such that the active regions OD11, OD12, and OD13 protrude above the top surface of the recessed dielectric isolation structure 111 to form fin-like structures, which in turn allows for forming FinFET devices over the active regions OD11, OD12, and OD13.

The integrated circuit structure in the memory system 100 as shown in FIGS. 1E-1G may further include gate structures G11, gate structures G12, and gate structures G13 extending within the memory array region 101 and the peripheral circuit region 102 and across the active regions OD11, OD12, and OD13 along the Y-direction perpendicular to the X-direction. The gate structures G11, G12, and G13 can have a strip shape from the top view and are thus interchangeably referred to as metal gate strips in this context. In some embodiments, the gate structures G11, G12, and G13 can be interchangeably referred to as gates, metal gates, gate layers, or gate patterns. In some embodiments as illustrated in FIG. 1A, the gate structures G11, G12, and G13 are arranged in a first row along the X-direction. The gate structures G11, G12, and G13 are on same level height.

In some embodiments, the gate structures G11, G12, and G13 are functional high-k metal gate (HKMG) gate structures. The functional HKMG gate structures G11, G12, and G13 are formed using a same gate-last process flow (interchangeably referred to as gate replacement flow), which will be explained in greater detail below. As a result of the gate-last process flow, each of the gate structures G11, G12, and G13 includes one or more gate electrode layers 117 and a gate dielectric layer 116 lining a bottom surface and sidewalls of the one or more gate electrode layers 117, so that the gate dielectric layer 116 has a U-shaped cross section as illustrated in FIG. 1F.

The integrated circuit structure in the memory system 100 as shown in FIGS. 1E-1G may further include a plurality of source/drain regions S/D11, S/D12, and S/D13 in the active regions OD11, OD12, and OD13. The source/drain regions S/D11, S/D12, and S/D13 are doped semiconductor regions located on opposite sides of the corresponding gate structures G11, G12, and G13. In some embodiments, the source/drain regions S/D11, S/D12, and S/D13 include p-type dopants or impurities such as boron for forming functional p-type FETs in the active regions OD11, OD12, and OD13. In some other embodiments, the source/drain regions S/D11, S/D12, and S/D13 include n-type dopants or impurities such as phosphorus for forming functional n-type FETs in the active regions OD11, OD12, and OD13. In some embodiments, a plurality of source/drain contacts MD11, MD12, MD13 (see FIG. 1A) can be formed to land on the respective source/drain regions S/D11, S/D12, and S/D13 within the active regions OD11, OD12, and OD13. In some embodiments, the source/drain contacts MD11, MD12, MD13 may include suitable one or more metals, such as W, Cu, the like or combinations thereof.

In some embodiments, the source/drain regions S/D11, S/D12, and S/D13 may be epitaxially grown regions. For example, gate spacers 113 may be formed alongside sacrificial gate structures (which will be replaced with the gate structures G11, G12, and G13) by depositing a spacer material and anisotropically etching the spacer material, and subsequently, the source/drain regions S/D11, S/D12, and S/D13 may be formed self-aligned to the gate spacers 113 by first etching the active regions OD11, OD12, and OD13 to form recesses, and then depositing a crystalline semiconductor material in the recesses by a selective epitaxial growth (SEG) process that may fill the recesses in the active regions OD11, OD12, and OD13 and may extend further beyond the original surface of the active regions OD11, OD12, and OD13 to form raised source/drain epitaxy structures in some embodiments. The crystalline semiconductor material may be an elemental semiconductor (e.g., Si, or Ge, or the like), or an alloy semiconductor (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁴ cm⁻² to 10¹⁶ cm⁻²) of n-type or p-type dopants may be introduced into source/drain regions S/D11, S/D12, and S/D13 either in situ during SEG, or by an ion implantation process performed after the SEG, or by a combination thereof.

The integrated circuit structure in the memory system 100 as shown in FIGS. 1E-1G may further include a plurality of gate contacts VG11, VG12, and VG13 over the corresponding gate structures G11, G12, and G13, respectively, and at least two of the gate contacts VG11, VG12, and VG13 have different contact locations on the corresponding gate structures G11, G12, and G13. By way of example and not limitation, as illustrated in FIG. 1F, the gate contacts VG11 can be positioned between the outermost edges B11 of the active regions OD11, the gate contacts VG12 can be positioned between the outermost edges B12 of the active regions OD12, and the gate contacts VG13 can be positioned outside a space between the outermost edges B13 of the active regions OD13. This gate contact configurations can increase the threshold voltage of the transistors T11 in the memory array region 101, hence reducing the current leakage, reduce the threshold voltage of the transistors T12 in the sense amplifier, thus expanding the read window and enhancing the sense amplifier's performance, and maintain a stable threshold voltage for the transistor T13, thus decreasing the threshold voltage shifts, which contributes to an efficient power utilization within the memory system 100.

In some embodiments, the gate contact VG11 and/or the gate contact VG12 may overlap with the active region OD11 and/or the active region OD12. In some embodiments, the gate contact VG11 and/or the gate contact VG11 may non-overlap with the active region OD11 and/or the active region OD12. In some embodiments, the gate contact VG11 is spaced apart from the edge B11 of the active regions OD11 by at least a lateral distance D5, the gate contacts VG12 is spaced apart from the edge B12 of the active region OD12 by at least a lateral distance D6, and the gate contact VG13 is spaced apart from the edge B13 of the active region OD13 by at least a lateral distance D7. By way of example and not limitation, the distance D5 may be in a range from about 5 to 60 nm, such as about 5, 6, 7, 8, 9, 10, 11, 12, 13, 14, 15, 20, 25, 30, 35, 40, 45, 50, 55, or 60 nm. In some embodiments, the distance D6 may be in a range from about 5 to 60 nm, such as about 5, 6, 7, 8, 9, 10, 11, 12, 13, 14, 15, 20, 25, 30, 35, 40, 45, 50, 55, or 60 nm. In some embodiments, the distance D7 may be in a range from about 15 to 60 nm, such as about 15, 16, 17, 18, 19, 20, 21, 22, 23, 24, 25, 30, 35, 40, 45, 50, 55, or 60 nm.

In some embodiments, the gate contacts VG11, VG12, and VG13 may include a conductive material such as, for example, copper (Cu), tungsten (W) cobalt (Co) or other suitable metals. Formation of the gate contacts VG11, VG12, and VG13 may include, for example, etching contact openings in an interlayer dielectric (ILD) layer 118 over the gate structures G11, G12, and G13, depositing one or more conductive materials in the contact openings, and planarizing the one or more conductive materials by using, for example, a CMP process.

Referring to FIG. 1D, the bit-cell 103 with the memory array region 101 can be an eFuse cell. The bit-cell 103 can be implemented as a 1T1R configuration, for example, a fuse resistor 104 can be serially connected to the access transistor T11. It, however, should be understood that any of various other fuse configurations that exhibit the fuse characteristic may be used by the bit-cell 103 such as, for example, a 2-diodes-1-resistor (2D1R) configuration, a many-transistors-one-resistor (manyT1R) configuration, etc., while remaining within the scope of the present disclosure. In some embodiments, the fuse resistor 104 can be formed of one or more metal structures. For example, the fuse resistor 104 may be one of a number of interconnect structures in one of a number metallization layers that are disposed above the access transistor T11. Specifically, the access transistor T11 is formed over the substrate 110 (see FIGS. 1E-1G), which is sometimes referred to as part of front-end-of-line (FEOL) processing. Over the FEOL processing, a number of metallization layers, each of which includes a number of interconnect (e.g., metal) structures, are typically formed, which are sometimes referred to as part of back-end-of-line (BEOL) processing. During the BEOL processing, or between the FEOL and BEOL processing, there can be processing steps where local electrical connections between transistors and metal gate contacts are formed during the middle-end-of-line (MEOL) processing.

In some embodiments, the fuse resistor 104 can include bottom and top electrode layers 104a and 104c (see FIG. 1N) and a fuse layer 104b (see FIG. 1N) between the bottom and top electrode layers 104a and 104c. In some embodiments, one of the source/drain regions S/D11 of the transistor T11 can be electrically connected to the source line SL11, another one of the source/drain regions S/D11 of the transistor T11 can be electrically connected to the bit line BL11, and the gate structures G11 can be electrically connected to the word line WL11. With the fuse resistor 104 (of the bit-cell 103) embodied as a metal structure, the fuse resistor 104 may present an initial resistance value (or resistivity), for example, as fabricated. To program the bit-cell 103, the access transistor T11 (if embodied as an n-type transistor) is turned on by applying a (e.g., voltage) signal, corresponding to a logic high state, through a word line WL11 to the gate structures G11 of the access transistor T11. Concurrently or subsequently, a high enough (e.g., voltage) signal is applied on one of the terminals of the fuse resistor 104 through a bit line BL11. With the access transistor T11 turned on to provide a (e.g., program) path from the bit line BL, through the fuse resistor 104 and access transistor T11, and to a source line SL11, such a high voltage signal can burn out a portion of the corresponding metal structure (e.g., the fuse resistor 104), thereby transitioning the fuse resistor 104 from a first state (e.g., a short circuit) to a second state (e.g., an open circuit). Accordingly, the bit-cell 103 can irreversibly transition from a first logic state (e.g., logic 0) to a second logic state (e.g., logic 1), which can be read out by applying a relatively low voltage signal on the bit line BL11 and turning on the access transistor T11 to provide a (e.g., read) path.

Reference is made to FIGS. 1H-1J. FIG. 1I illustrates a cross-sectional view of a semiconductor structure, with the nano-FET devices, corresponding to FIG. 1F in accordance with some embodiments of the present disclosure. FIG. 1J illustrates a cross-sectional view of the semiconductor structure corresponding to FIG. 1G, with the nano-FET devices, in accordance with some embodiments of the present disclosure. Specifically, at least one of the transistors T11, T12, and T13 in the memory system 100 as shown in FIG. 1A can be replaced with at least one of the transistors T11′, T12′, and T13′ being of nano-FET (e.g., nanowire FETs, nanosheet FETs, or the like) devices as shown in FIG. 1H. The nano-FETs may be nanosheet field-effect transistors (NSFETs), nanowire field-effect transistors (NWFETs), gate-all-around field-effect transistors (GAAFETs), or the like. As shown in FIGS. 1H-1J, the transistors T11′, T12′, and T13′ include active regions OD11′, OD12′, OD13′ (e.g., nanostructures, nanosheets, nanowires, or the like) over fins 214 on a substrate 210, with the active regions OD11′, OD12′, OD13′ acting as channel regions for the transistors T11′, T12′, and T13′. In some embodiments, the active regions OD11′, OD12′, and OD13′ each can be bordered by a first outer edge B11′, B12′, or B13′ of the channel region (e.g., nanostructures, nanosheets, nanowires, or the like) and a second outer edge B11′, B12′, or B13′ of the channel region (e.g., nanostructures, nanosheets, nanowires, or the like) opposite to the first outer edge B11′, B12′, or B13′ from a top view, each of the active regions OD11′, OD12′, and OD13′ can be bordered by a first outer edge of the channel region (e.g.) and a second outer edge of the channel region (e.g.) opposite to the first outer edge from a top view.

A dielectric isolation structure 211, such as a shallow trench isolation (STI), can be formed to laterally surround the fin 214. The dielectric isolation structure 111 can define and electrically isolate the active regions OD11, OD12, and OD13 of the transistors T11, T12, and T13.

In some embodiments, the active regions OD11′, OD12′, OD13′ may include p-type nanostructures, n-type nanostructures, or a combination thereof and extend along an X-direction. In some embodiments, the active regions OD11′, OD12′, OD13′ can be interchangeably referred to as channel patterns, channel regions, nanostructures, nanosheets, nanowires. The structure and material of the substrate 210 is substantially the same as the structure 110 shown in FIGS. 1E-1G, and the related detailed descriptions may refer to the foregoing paragraphs, and are not described again herein.

In some embodiments, the transistor T11′ can include the active region OD11′, the source/drain regions S/D11′ on opposite sides of the active region OD11′ and connected to the active region OD11′, and the gate structure G11′ wrapping around the active region OD11′, the transistor T12′ can include the active region OD12′, the source/drain regions S/D12′ on opposite sides of the active region OD12′ and connected to the active region OD12′, and the gate structure G12′ wrapping around the active region OD11′, the transistor T13′ can include the active region OD13′, the source/drain regions S/D13′ on opposite sides of the active region OD13′ and connected to the active region OD13′, and the gate structure G13′ wrapping around the active region OD13′. The transistor T11′ can be located in the memory array region 101, and the transistors T12′ and T13′ can be located in the peripheral circuit region 102. Gate spacers 213 may be formed alongside sacrificial gate structures G11′, G12′, and G13′ (see FIG. 1J). The structure and material of the gate spacer 213 is substantially the same as the gate spacer 113 shown in FIGS. 1E-1G, and the related detailed descriptions may refer to the foregoing paragraphs, and are not described again herein.

Therefore, in the memory array region 101's bit-cell 103 as shown in FIG. 1A, a minimize leakage in the memory system 100 can be achieved by enhancing the threshold voltage of transistor T11′. Therefore, the transistor T11′ can employ an NMOS transistor, with gate contacts VG11′ overlapping with active region OD11′ of the transistor T11′. This configuration can increase the threshold voltage, hence reducing the current leakage. In addition, for the sense amplifier within the peripheral circuit region 102 as shown in FIG. 1A, an improved read window can be achieved by reduction of the threshold voltage of the transistor T12′ as the sense amplifier. Therefore, the transistor T12′ can employ a PMOS transistor, with gate contacts VG12′ overlapping with the active region OD12′ of the transistor T12′. This configuration can reduce the threshold voltage, thus expanding the read window and enhancing the sense amplifier's performance. Moreover, for the power header within the peripheral circuit region 102 as shown in FIG. 1A, an efficient power utilization can be achieved by stability in the threshold voltage of the transistor T13′ as the power header. Therefore, the transistor T13′ can employ a NMOS transistor or a PMOS transistor, with gate contacts VG13′ non-overlapping with the active region OD13′ of the transistor T13′. This configuration can maintain a stable threshold voltage for the transistor T13′, devoid of threshold voltage shifts, which contributes to an efficient power utilization within the memory system 100.

Specifically, an ILD layer 228 can be formed over the gate structures G11′, G12′, and G13′ of the transistors T11′, T12′, and T13′, respectively, by using suitable deposition techniques, and then the gate contacts VG11′, VG12′, and VG13′ are formed in the ILD layer 228 and over the corresponding gate structures G11′, G12′, and G13′. At least two of the gate contacts VG11′, VG12′, and VG13′ have different contact locations on the corresponding gate structures G11′, G12′, and G13′. By way of example and not limitation, as depicted in FIG. 1I, the gate contacts VG11′ can be positioned between the outermost edges B11′ of the active regions OD11′, the gate contacts VG12′ can be positioned between the outermost edges B12′ of the active regions OD12′, and the gate contacts VG13′ can be positioned outside a space between the outermost edges B13′ of the active regions OD13′. This gate contact configurations can increase the threshold voltage of the transistors T11′ in the memory array region 101, hence reducing the current leakage, reduce the threshold voltage of the transistors T12′ in the sense amplifier, thus expanding the read window and enhancing the sense amplifier's performance, and maintain a stable threshold voltage for the transistor T13′, thus decreasing the threshold voltage shifts, which contributes to an efficient power utilization within the memory system 100. In some embodiments, the ILD layer 228 may include silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof.

In some embodiments, the gate contact VG11′ and/or the gate contact VG12′ may overlap with the active region OD11′ and/or the active region OD12′. In some embodiments, the gate contact VG11′ and/or the gate contact VG11′ may non-overlap with the active region OD11′ and/or the active region OD12′. In some embodiments, the gate contact VG11′ is spaced apart from the edge B11′ of the active regions OD11′ by at least a lateral distance D5′, the gate contacts VG12′ is spaced apart from the edge B12′ of the active region OD12′ by at least a lateral distance D6′, and the gate contact VG13′ is spaced apart from the edge B13′ of the active region OD13′ by at least a lateral distance D7′. By way of example and not limitation, the distance D5′ may be in a range from about 5 to 60 nm, such as about 5, 6, 7, 8, 9, 10, 11, 12, 13, 14, 15, 20, 25, 30, 35, 40, 45, 50, 55, or 60 nm. In some embodiments, the distance D6′ may be in a range from about 5 to 60 nm, such as about 5, 6, 7, 8, 9, 10, 11, 12, 13, 14, 15, 20, 25, 30, 35, 40, 45, 50, 55, or 60 nm. In some embodiments, the distance D7′ may be in a range from about 15 to 60 nm, such as about 15, 16, 17, 18, 19, 20, 21, 22, 23, 24, 25, 30, 35, 40, 45, 50, 55, or 60 nm.

In some embodiments, each of the gate structures G11′, G12′, and G13′ includes one or more gate electrode layers 217 and a gate dielectric layer 216. The gate dielectric layers 216 can be formed over top surfaces of the fins 214 and along top surfaces, sidewalls, and bottom surfaces of the active regions OD11′, OD12′, OD13′. The gate electrode layers 217 are formed over the gate dielectric layer 216. In some embodiments, the gate dielectric layer 216 may include a dielectric material having a k-value greater than about 7.0, such as a metal oxide or a silicate of hafnium, aluminum, zirconium, lanthanum, manganese, barium, titanium, lead, and combinations thereof. Although a single-layered gate dielectric layer 216 is illustrated in FIGS. 1H-1J, as will be subsequently described in greater detail, the gate dielectric layer 216 may include any number of interfacial layers and any number of main layers. In some embodiments, the gate electrode layers 217 may include a metal-containing material such as titanium nitride, titanium oxide, tungsten, cobalt, ruthenium, aluminum, combinations thereof, multi-layers thereof, or the like. Although a single-layered gate electrode layers 127 is illustrated in FIGS. 1H-1J, as will be subsequently described in greater detail, the gate electrode layer 217 may include any number of work function tuning layers, any number of barrier layers, any number of glue layers, and a fill material. In some embodiments, the gate electrode layers 217 may be made of a material selected from a group including TiN, TaN, TiAl, TiAlN, TaAl, TaAlN, TaAlC, TaCN, WNC, Co, Ni, Pt, W, or combinations thereof.

In some embodiments, source/drain regions S/D11′, S/D12′, and S/D13′ are formed to dispose on the fins 214 at opposing sides of the gate dielectric layers 216 and the gate electrode layers 217. The source/drain regions S/D11′, S/D12′, and S/D13′ may be shared between various fins 214. For example, the adjacent source/drain regions S/D11′. S/D12′, and S/D13′ may be electrically connected, such as through coalescing the source/drain regions S/D11′, S/D12′, and S/D13′ by epitaxial growth, or through coupling the source/drain regions S/D11′, S/D12′, and S/D13′ with a same source/drain contact. An ILD layer 218 can be formed over the source/drain regions S/D11′. S/D12′, and S/D13′ by depositing a dielectric material over the substrate 210. In some embodiments, the ILD layer 218 may include silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. Source/drain contacts MD11′, MD12′, MD13′ can be formed to land on the respective source/drain regions S/D11′, S/D12′, and S/D13′.

In some embodiments, a fuse resistor (not shown) can be serially connected to the access transistor T11′. The structure and function of the components and their relationships between the transistor T11′ and the fuse resistor are substantially the same as the transistor T11 and the fuse resistor 104 shown in FIGS. 1D-1G, and the related detailed descriptions may refer to the foregoing paragraphs, and are not described again herein.

In some embodiments, inner spacers 219 can be formed between the source/drain regions S/D11′, S/D12′, and S/D13′ and the corresponding gate structures G11′, G12′, and G13′ and serve to isolate the gate structures G11′, G12′, and G13′ from source/drain regions S/D11′, S/D12′, and S/D13′. The inner spacer 219 may be a low-k dielectric material, such as SiO₂, silicon nitride (SiN), silicon carbonoxide (SiCO), silicon carbonnitride (SiCN), silicon oxycarbonnitride (SiOCN). The inner spacer 219 can be formed using CVD, including LPCVD and PECVD, PVD, ALD, or other suitable processes. In the example of FIG. 1J, sidewalls of the inner spacers 219 are substantially aligned with sidewalls of the active regions OD11′, OD12′, OD13′.

In some embodiments, dielectric isolation structures 211, such as shallow trench isolation (STI) regions, are disposed between adjacent fins 214, which may protrude above and from between adjacent dielectric isolation structures 211. Although the dielectric isolation structures 211 are described/illustrated as being separate from the substrate 210. Additionally, although a bottom portion of the fins 214 are illustrated as being single, continuous materials with the substrate 210, the bottom portion of the fins 214 and/or the substrate 210 may include a single material or a plurality of materials.

Reference is made to FIGS. 1K-1M. FIG. 1L illustrates a cross-sectional view of a semiconductor structure, with the TFT devices, corresponding to FIG. 1F in accordance with some embodiments of the present disclosure. FIG. 1M illustrates a cross-sectional view of the semiconductor structure corresponding to FIG. 1G, with the TFT devices, in accordance with some embodiments of the present disclosure. Specifically, at least one of the transistors T11, T12, and T13 in the memory system 100 as shown in FIG. 1A can be replaced with at least one of the transistors T11″, T12″, and T13″ being of TFT device as shown in FIG. 1K. In some embodiments, the transistor T11″ can include the channel region 312a, the source/drain regions S/D11″ (see FIG. 1M) on opposite sides of the channel region 312a and connected to the channel region 312a, and the gate structure G11″ formed on the channel region 312a. The transistor T12″ can include the channel region 312b, the source/drain regions S/D12″ (see FIG. 1M) on opposite sides of the channel region 312b and connected to the channel region 312b, and the gate structure G12″ formed on the channel region 312b. The transistor T13″ can include the channel region 312c, the source/drain regions S/D13″ (see FIG. 1M) on opposite sides of the channel region 312c and connected to the channel region 312c, and the gate structure G13″ formed on the channel region 312c. The transistor T11″ can be located in the memory array region 101, and the transistors T12″ and T13″ can be located in the peripheral circuit region 102.

Therefore, in the memory array region 101's bit-cell 103 as shown in FIG. 1A, a minimize leakage in the memory system 100 can be achieved by enhancing the threshold voltage of transistor T11″. Therefore, the transistor T11″ can employ an NMOS transistor, with gate contacts VG11″ overlapping with active region OD11″ of the transistor T11″. This configuration can increase the threshold voltage, hence reducing the current leakage. In some embodiments, the active regions OD11″, OD12″, and OD13″ each can be bordered by a first outer edge B11″, B12″, or B13″ of the channel region 312a, 312b, or 312c and a second outer edge B11″, B12″, or B13″ of the channel region 312a. 312b, or 312c opposite to the first outer edge B11″, B12″, or B13″ from a top view.

In addition, for the sense amplifier within the peripheral circuit region 102 as shown in FIG. 1A, an improved read window can be achieved by reduction of the threshold voltage of the transistor T12″ as the sense amplifier. Therefore, the transistor T12″ can employ a PMOS transistor, with gate contacts VG12″ overlapping with the active region OD12″ of the transistor T12″. This configuration can reduce the threshold voltage, thus expanding the read window and enhancing the sense amplifier's performance. Moreover, for the power header within the peripheral circuit region 102 as shown in FIG. 1A, an efficient power utilization can be achieved by stability in the threshold voltage of the transistor T13″ as the power header. Therefore, the transistor T13″ can employ a NMOS transistor or a PMOS transistor, with gate contacts VG13″ non-overlapping with the active region OD13″ of the transistor T13″. This configuration can maintain a stable threshold voltage for the transistor T13″, devoid of threshold voltage shifts, which contributes to an efficient power utilization within the memory system 100.

As shown in FIGS. 1L and 1M, the gate contacts VG11″, VG12″, and VG13″ can be formed over the corresponding gate structures G11″, G12″, and G13″ of the transistors T11″, T12″, and T13″, respectively, and at least two of the gate contacts VG11″, VG12″, and VG13″ have different contact locations on the corresponding gate structures G11″, G12″, and G13″. By way of example and not limitation, as depicted in FIG. 1L, the gate contacts VG11″ can be positioned between the outermost edges B11″ of the active regions OD11″, the gate contacts VG12″ can be positioned between the outermost edges B12′ of the active regions OD12″, and the gate contacts VG13″ can be positioned outside a space between the outermost edges B13″ of the active regions OD13″. This gate contact configurations can increase the threshold voltage of the transistors T11″ in the memory array region 101, hence reducing the current leakage, reduce the threshold voltage of the transistors T12″ in the sense amplifier, thus expanding the read window and enhancing the sense amplifier's performance, and maintain a stable threshold voltage for the transistor T13″, thus decreasing the threshold voltage shifts, which contributes to an efficient power utilization within the memory system 100.

In some embodiments, the gate contact VG11″ and/or the gate contact VG12″ may overlap with the active region OD11″ and/or the active region OD12″. In some embodiments, the gate contact VG11″ and/or the gate contact VG11″ may non-overlap with the active region OD11″ and/or the active region OD12″. In some embodiments, the gate contact VG11″ is spaced apart from the edge B11″ of the active regions OD11″ by at least a lateral distance D5″, the gate contacts VG12″ is spaced apart from the edge B12″ of the active region OD12″ by at least a lateral distance D6″, and the gate contact VG13″ is spaced apart from the edge B13″ of the active region OD13″ by at least a lateral distance D7″. By way of example and not limitation, the distance D5″ may be in a range from about 5 to 60 nm, such as about 5, 6, 7, 8, 9, 10, 11, 12, 13, 14, 15, 20, 25, 30, 35, 40, 45, 50, 55, or 60 nm. In some embodiments, the distance D6″ may be in a range from about 5 to 60 nm, such as about 5, 6, 7, 8, 9, 10, 11, 12, 13, 14, 15, 20, 25, 30, 35, 40, 45, 50, 55, or 60 nm. In some embodiments, the distance D7″ may be in a range from about 15 to 60 nm, such as about 15, 16, 17, 18, 19, 20, 21, 22, 23, 24, 25, 30, 35, 40, 45, 50, 55, or 60 nm.

In some embodiments, a method of forming transistors T11″, T12″, and T13″ can be described as an example. For example, insulating layers 320 can be formed over the substrate 310. The structure and material of the substrate 310 is substantially the same as the structure 110 shown in FIGS. 1E-1G, and the related detailed descriptions may refer to the foregoing paragraphs, and are not described again herein.

Subsequently, the gate structures G11″, G12″, and G13″ can be formed over the insulating layers 320. Each of the gate structures G11″, G12″, and G13″ may include a gate electrode layer 317 and a gate dielectric layer 316.

By way of example and not limitation, a gate electrode material can be formed over the insulating layers 320 by a physical vapor deposition (PVD) process, exposed to radiation, and dry-etched to obtain gate electrode layers 317. In some embodiments, the gate electrode layer 317 may include Al, Ti, TiN, TaN, Co, Ag, Au, Cu, Ni, Cr, Hf, Ru, W, Pt, WN, Ru, combinations thereof, or the like. A gate dielectric layer 316 can be conformally deposited as a blanket layer over the gate electrode layer 317. In some embodiments, the gate dielectric layer 316 includes one or more high-k dielectric layers. High-k gate dielectrics, as used and described herein, include dielectric materials having a high dielectric constant, for example, greater than that of thermal silicon oxide (about 3.9). The high-k dielectric material of the gate dielectric layer 316 may include, by way of example and not limitation, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (La₂O₃), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

Subsequently, the active regions OD11″, OD12″, and OD13″ can be conformally formed over the gate structures G11″, G12″, and G13″. Specifically, a channel material can be conformally deposited as a blanket layer over the gate dielectric layers 316, and patterned to separate the continuous channel material into individual active regions OD11″, OD12″, and OD13″ conformally over the gate dielectric layers 316. For example, photolithography and etching processes (as described above) are performed to pattern the channel material. In some embodiments, the channel material is patterned by using a selective etching process. Because the channel material can be formed of a different material than the gate dielectric layer 316, etching chemicals of the selective etching process can be selected to etch the channel material at a faster etch rate than etching the gate dielectric layer 316. In some embodiments, the active regions OD11″, OD12″, and OD13″. The active regions OD11″, OD12″, and OD13″ each can be made of semiconductor materials that can form ohmic contact with the source line (not shown), and thus the active regions OD11″, OD12″, and OD13″ can have source/drain regions S/D11″, S/D12″, and S/D13″ that do not require doped regions, like n-type or p-type doped regions in bulk silicon of CMOS transistors. In some embodiments, the active regions OD11″, OD12″, and OD13″ may include indium gallium zinc oxide (InGaZnO, IGZO), indium tin oxide (ITO), indium zinc oxide (IZO), zinc oxide (ZnO), indium tungsten oxide (IWO), combinations thereof, or the like. In some embodiments, the active regions OD11″, OD12″, and OD13″ can have channel regions 312a, 312b, and 312c between the corresponding source/drain regions S/D11″, S/D12″, and S/D13″.

Subsequently, source/drain contacts MD11″, MD12″, MD13″ can be conformally formed over the active regions OD11″, OD12″, and OD13″. Specifically, a source/drain contact material can be conformally deposited as a blanket layer over the active regions OD11″, OD12″, and OD13″, and patterned to separate the continuous source/drain contact material into individual source/drain contacts MD11″. By way of example and not limitation, in the case of the active regions OD11″, OD12″, and OD13″ of the transistors T11″, T12″, and T13″ including metal-oxide semiconductors, such as IGZO, the active regions OD11″, OD12″, and OD13″ can be intrinsic (i.e., neither n-type nor p-type). The behavior as either NMOS or PMOS can be determined by the application of voltages at the gate structures G11″, G12″, and G13″ and by the work function of the materials used for the source/drain contacts MD11″, MD12″, MD13″. Essentially, the transistors T11″, T12″, and T13″ can be designed to accumulate either electrons or holes at the interface of the active regions OD11″, OD12″, and OD13 and the gate dielectric layers 316, based on the applied gate voltage and the work function of the source/drain contacts MD11″, MD12″, MD13″, making it functionally similar to an NMOS or PMOS device, respectively. For example, if the work function of the source/drain contacts MD11″, MD12″, and/or MD13″ can align with the conduction band of the semiconductor, an electron accumulation layer can form at the interface when a suitable gate voltage is applied, resulting in an n-type transistor. If the work function of the source/drain contacts MD11″, MD12″, and/or MD13″ can align with the valence band of the semiconductor, a hole accumulation layer can form, resulting in a p-type transistor.

Therefore, the portions of the active regions OD11″, OD12″, and OD13″ covering by the source/drain contacts MD11″, MD12″, MD13″ can serve as source/drain regions S/D11″, S/D12″, and S/D13″, and the portion of the active regions OD11″, OD12″, and OD13″ free from coverage by the source/drain contacts MD11″, MD12″, MD13″ can serve as can serve as the channel regions 312a, 312b, and 312c (see FIG. 1M). In some embodiments, the source/drain contacts MD11″, MD12″, MD13″ may include Al, Ti, TIN, TaN, Co, Ag, Au, Cu, Ni, Cr, Hf, Ru, W, Pt, WN, Ru, combinations thereof, or the like. In some embodiments, the source/drain contacts MD11″, MD12″, MD13″ can be interchangeably referred to as source/drain films, source/drain layers, or source/drain patterns. In some embodiments, an ILD layer 318 can be formed over the source/drain contacts MD11″, MD12″, MD13″ by depositing a dielectric material over the substrate 310. In some embodiments, the ILD layer 318 may include silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof.

Subsequently, source/drain vias 322 can be formed on the source/drain contacts MD11″, MD12″, MD13″. The source/drain vias 322 may include a metal-containing material such as titanium nitride, titanium oxide, tungsten, cobalt, ruthenium, aluminum, copper, combinations thereof, multi-layers thereof, or the like. Subsequently, a fuse resistor (not shown) can be serially connected to the access transistor T11″. The structure and function of the components and their relationships between the transistor T11″ and the fuse resistor are substantially the same as the transistor T11 and the fuse resistor 104 shown in FIGS. 1D-1G, and the related detailed descriptions may refer to the foregoing paragraphs, and are not described again herein.

Reference is made to FIGS. 1N-1R. FIGS. 1N, 1P, and 1R illustrate cross-sectional views of semiconductor structures in accordance with some embodiments of the present disclosure. FIGS. 1O and 1Q illustrate local enlarged views of semiconductor structures corresponding to regions C7 and C8 in FIGS. 1N and 1P in accordance with some embodiments of the present disclosure. While FIGS. 1N-1R show embodiments of semiconductor structures with different cross-sectional view profiles than the semiconductor structure in FIGS. 1H-1M. In addition, the present disclosure may repeat reference numerals and/or letters in the various examples. This repetition is for the purpose of simplicity and clarity and does not in itself dictate a relationship between the various embodiments and/or configurations discussed.

Specifically, the memory array region 101 as shown in FIG. 1A can be formed at a different level height than the peripheral circuit region 102, such that the peripheral circuit region 102 can be distributed in the same device area as the memory array region 101, and the transistors (e.g., transistor T12′/T13′ as shown in FIGS. 1G-11) in the peripheral circuit region 102 may overlap with transistors (e.g., transistor T11″ as shown in FIGS. 1K-1M) in the memory array region 101. As shown in FIGS. 1N-1R, the memory array region 101 can be at a higher level height than the peripheral circuit region 102. In some embodiments, the memory array region 101 can be at a lower level height than the peripheral circuit region 102. In addition, the transistors in the peripheral circuit region 102 can be of a different device type than the in the memory array region 101. By way of example and not limitation, the transistor (e.g., transistor T12′/T13′ as shown in FIGS. 1G-11) in the peripheral circuit region 102 can be of GAA device, and the transistor (e.g., transistor T11″ as shown in FIGS. 1K-1M) in the memory array region 101 can be of TFT device.

As shown in FIG. 1N, after the forming of the transistor T12′/T13′, a BEOL routing structure 330 can be formed over the transistor T12′/T13′ and is illustrated in a schematic manner, without detailing the interconnections. In some embodiment, the transistor T12′ can be of a sense amplifier, and the transistor T13′ can be of a power header. In some embodiments, an improved read window can be achieved by reduction of the threshold voltage of the transistor T12′. Therefore, the transistor T12′ can employ a PMOS transistor, with the gate contact (see VG12 as shown in FIGS. 1L and 1M) overlapping with the active region OD12′ of the transistor T12′. In some embodiments, an efficient power utilization can be achieved by stability in the threshold voltage of the transistor T13′. Therefore, the transistor T13′ can employ a NMOS transistor or a PMOS transistor, with the gate contact (see VG13 as shown in FIGS. 1L and 1M) non-overlapping with the active region OD13′ of the transistor T13′.

In some embodiments, the BEOL routing structure 330 can be formed using a BEOL process. The BEOL process involves forming the metal wiring between the device structures over the substrate 210 in order to interconnect them including forming contacts, interconnect wires, via structures, and dielectric structures. Subsequently, dielectric layers 331 and 332 can be formed over the BEOL routing structure 330. In some embodiments, the dielectric layers 331 and 332 may include silicon oxide, SiCN, or any other suitable materials.

Subsequently, the transistor T11″ being of a memory cell (e.g., efuse memory cell) can be formed over the transistor T12′/T13′ and laterally surrounded by a dielectric layer 318. The transistors T11″ can be implemented in a 1T1R array configuration and include the channel region 312a, the source/drain regions S/D11″ on opposite sides of the channel region 312a and connected to the channel region 312a, and the gate structure G11″ formed on the channel region 312a. In some embodiments, a minimize leakage in the memory system can be achieved by enhancing the threshold voltage of transistor T11″. Therefore, the transistor T11″ can employ an NMOS transistor, with the gate contact (see VG11″ as shown in FIGS. 1L and 1M) overlapping with the active region OD11″ of the transistor T11″. This configuration can increase the threshold voltage, hence reducing the current leakage. In some embodiments, the stacked transistor T11″ (e.g., 3D indium gallium zinc oxide (IGZO) device) can achieve an efficient and precise control over the shift in threshold voltage (Vt), which in turn allows for distinctly separating the different shifts in Vt, thus optimizing the balance between a higher cell current and lower cell leakage. The higher cell current promotes improved performance, while the lower leakage current results in greater power efficiency. In addition, the stacked 3D transistor T11″ (e.g., stacked 3D IGZO device) can enable a smaller cell area, contributing to a more compact and efficient layout; on the contrary, the bit-cell current can be significantly boosted to achieve a bit-cell current, such as at least about three times larger than what other designs. The source/drain contacts MD11″ can be conformally formed over the active regions OD11″. The source/drain vias 322 can be formed on the source/drain contacts MD11″, MD12″, MD13″.

Subsequently, the fuse resistor 104 can be formed over the transistor T11″ and serially connected to the access transistor T11″. The fuse resistor 104 can include bottom and top electrode layers 104a and 104c and a fuse layer 104b between the bottom and top electrode layers 104a and 104c. The fuse layer 104b can be a metal-based layer formed of, but not limited to, TiOₓ, NiOₓ, HfOₓ, NbOₓ, CoOₓ, FeOₓ, CuOₓ, VOₓ, TaOₓ, WOₓ, CrOₓ, and combinations thereof. By way of example and not limitation, the fuse layer 104b can include material including tantalum nitride (TaN), alloy of Ti and TiN, alloy of Ta and TaN, or combinations thereof. In some embodiments, the bottom and top electrode layers 104a and 104c may include Al, Ti, TiN, TaN, Co, Ag, Au, Cu, Ni, Cr, Hf, Ru, W, Pt, WN, Ru, combinations thereof, or the like. The metal wirings 334 and 335 can be formed to sandwich the fuse resistor 104 in order to interconnect the fuse resistor 104 and the device structures (not shown) over the substrate 210. In some embodiments, the fuse resistor 104 and the metal wirings 334 and 335 can be formed in a dielectric layer 336.

Reference is made to FIG. 1O. The structure and function of a transistor T21″ including channel region 412a, source/drain regions S/D21″, and a gate structure G21″ formed on the channel region 412a are substantially the same as those of the transistor T11″ including channel region 312a, source/drain regions S/D11″, and a gate structure G11″ shown in FIG. 1N, and the related detailed descriptions may refer to the foregoing paragraphs, and are not described again herein. It is noted that, the difference between the present embodiment and the embodiment in FIG. 1N is in that the transistor T21″ can have a greater vertical dimension than the transistor T11″. As shown in FIG. 1O, the transistor T21″ can include the active region OD21″ having an inverted U-shaped cross-sectional profile. The transistor T21″ can be structured such that its vertical dimension can be greater than its lateral dimension, such that the vertical dimension R1 of the active region OD21″ can be enlarged and does not impact the 2D area, thereby preserving the device's compact footprint. In some embodiments, the vertical dimension R1 of the active region OD21″ is greater than the lateral dimension W1 of the active region OD21″. Increasing the vertical dimension R1 of the active region OD21″ can amplify the contact area between the source/drain region S/D21″ of the active region OD21″ and the corresponding metal contact MD21″. A larger contact area between the active region OD21″ and the metal contact MD21″ can reduce the contact resistance, thereby facilitating the flow of current. Specifically, a lower contact resistance means that the transistor T21″ can conduct a higher current, given the same voltage applied across it. Thus, by elevating the vertical dimension R1 of the active region OD21″, the transistor's current-driving capacity can be boosted, enhancing the overall performance of the transistor T21″ without necessitating additional 2D area.

Reference is made to FIG. 1P. The structure and function of source/drain contacts MD31″ and a transistor T31″ including channel region 512a (of an active region OD31″), source/drain regions S/D21″ (of the active region OD31″), and a gate structure G31″ formed on the channel region 512a are substantially the same as those of the source/drain contacts MD11″ and the transistor T11″ including the channel region 312a, the source/drain regions S/D11″, and the gate structure G11″ shown in FIG. 1N, and the related detailed descriptions may refer to the foregoing paragraphs, and are not described again herein. It is noted that, the difference between the present embodiment and the embodiment in FIG. 1N is in that the source/drain contacts MD31″ can be two layers landing on the dielectric layer 331. The active region OD31″ can be conformally formed on the source/drain contacts MD31″ and continuously laterally extends from one of the source/drain contacts MD31″ to another one of the source/drain contacts MD31″ along a top surface of the dielectric layer 332. The gate structures G31″ can include a gate electrode layer 517 and a gate dielectric layer 516. The gate dielectric layer 516 conformally formed on the active region OD31″, and the gate electrode layer 517 can be formed over the gate dielectric layer 516 and laterally between the source/drain contacts MD31″. In some embodiments, the source/drain vias 322 can be formed to extending through the active region OD31″ and the gate dielectric layer 516 and land on the source/drain contacts MD31″. Therefore, source/drain contact configuration can amplify the contact area between the source/drain region S/D31″ of the active region OD31″ and the corresponding metal contact MD31″. A larger contact area between the active region OD31″ and the metal contact MD31″ can reduce the contact resistance, thereby facilitating the flow of current. Specifically, a lower contact resistance means that the transistor T31″ can conduct a higher current, given the same voltage applied across it. Thus, the transistor's current-driving capacity can be boosted, enhancing the overall performance of the transistor T31″.

Reference is made to FIG. 1Q. The structure and function of a transistor T41″ including channel region 612a (of an active region OD41″), source/drain regions S/D41″ (of the active region OD41″), and a gate structure G41″ formed on the channel region 412a are substantially the same as those of the transistor T31″ including channel region 512a, source/drain regions S/D31″, and a gate structure G31″ shown in FIG. 1P, and the related detailed descriptions may refer to the foregoing paragraphs, and are not described again herein. It is noted that, the difference between the present embodiment and the embodiment in FIG. 1P is in that the transistor T41″ can have a greater vertical dimension than the transistor T31″. In FIG. 1Q, the vertical dimensions R3 and R4 of the source/drain contacts MD41″ and a gate electrode layer 617 of the gate structure G41″ can be enlarged and does not impact the 2D area, thereby preserving the device's compact footprint. In some embodiments, the vertical dimension R3 of the source/drain contact MD41″ can be greater than the vertical dimension R5 of the source/drain contact MD31″ as shown in FIG. 1P, and the vertical dimension R4 of the gate electrode layer 617 of the gate structure G41″ can be greater than the vertical dimension R6 of the gate electrode layer 517 of the gate structure G31″ as shown in FIG. 1P.

In some embodiments, increasing the vertical dimension R3 of the active region OD41″ can be amplified the contact area between the source/drain region S/D41″ of the active region OD41″ and the corresponding metal contact MD41″. A larger contact area between the active region OD41″ and the metal contact MD41″ can reduce the contact resistance, thereby facilitating the flow of current. Specifically, a lower contact resistance means that the transistor T41″ can conduct a higher current, given the same voltage applied across it. Thus, by elevating the vertical dimension R3 of the active region OD41″, the transistor's current-driving capacity can be boosted, enhancing the overall performance of the transistor T41″ without necessitating additional 2D area. In addition, increasing the vertical dimension R4 of the active region OD41″ can amplify the contact area between the source/drain region S/D41″ of the active region OD41″ and the corresponding metal contact MD41″, such that the contact area between the gate electrode layer 517 and the gate dielectric layer 616 of the gate structure G41″ can be amplified, which in turn improves the gate control. In some embodiments, a larger gate electrode-dielectric contact area means that the gate voltage can influence a larger volume of the semiconductor, thereby enhancing the control of the gate over the transistor's operation.

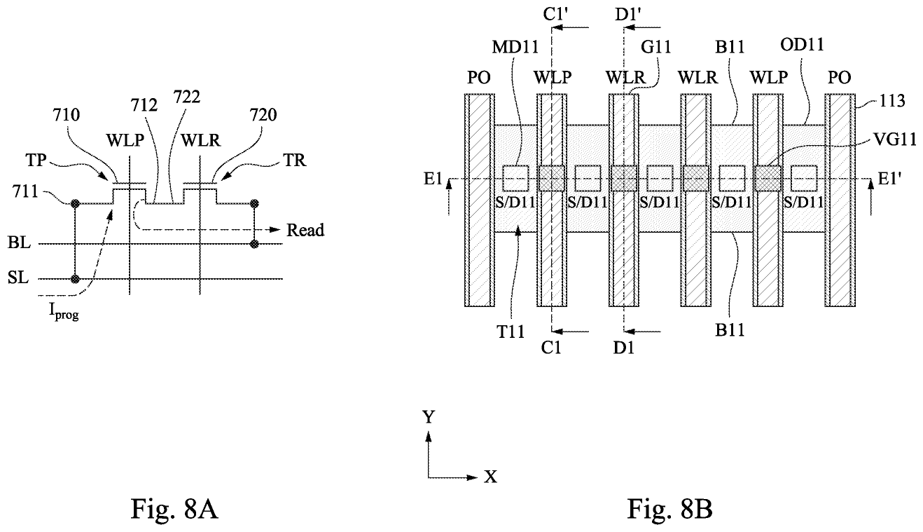

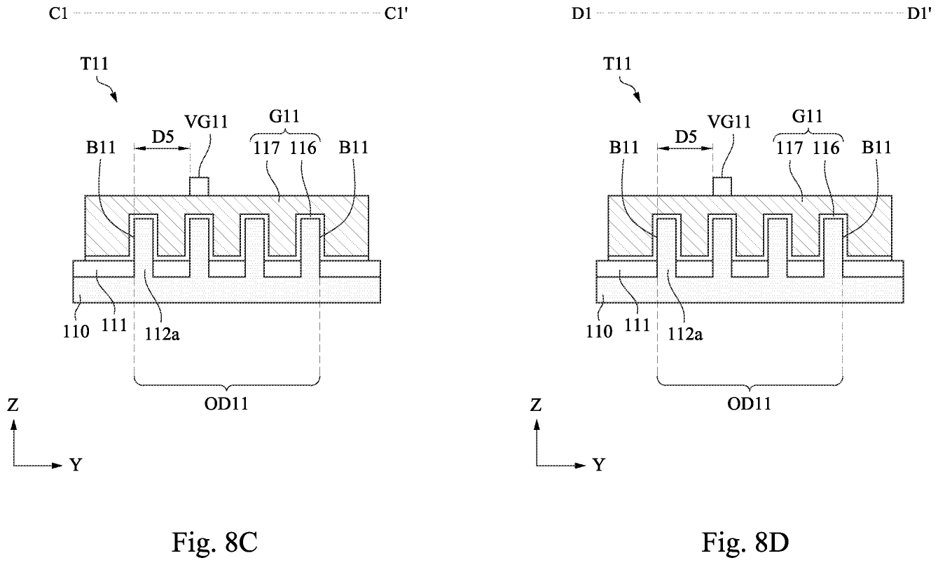

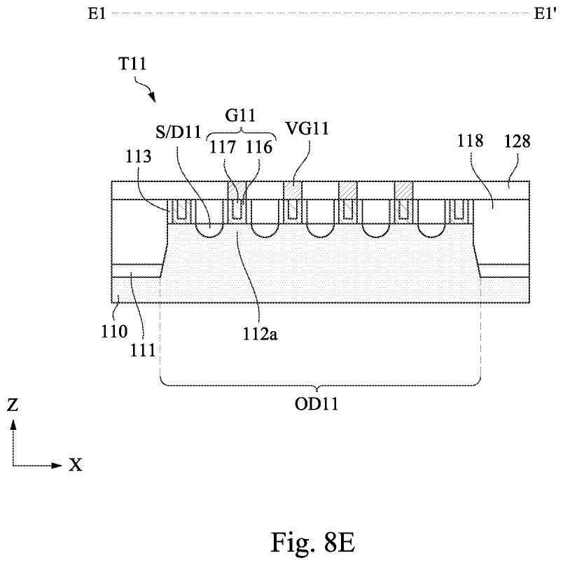

Reference is made to FIG. 1R. The structure and function of the structure are substantially the same as that of the structure as shown in FIG. 1N, and the related detailed descriptions may refer to the foregoing paragraphs, and are not described again herein. The difference between the embodiment in FIG. 1R and the embodiment in FIG. 1N is in that the transistor T11″ shown in FIG. 1R are of an anti-fuse memory cell, such that there are two transistors T11″ connected with each other by the source/drain region S/D11″, and the structure and function of the anti-fuse memory cell will be explained in greater detail below (see FIG. 8A).

Reference is made to FIGS. 2A-7B. FIGS. 2A-7B illustrate cross-sectional views of intermediate stages in the formation of a semiconductor structure in accordance with some embodiments of the present disclosure. FIGS. 2A, 3A, 4A, 5A, 6A, and 7A illustrate cross-sectional views obtained from the reference cross-sections A-A′, B-B′, and C-C′ in FIG. 1A. FIGS. 2B, 3B, 4B, 5B, 6B, and 7B illustrate cross-sectional views obtained from the reference cross-sections D-D′, E-E′, and F-F in FIG. 1A. It is understood that additional operations can be provided before, during, and after the processes shown by FIGS. 2A-7B, and some of the operations described below can be replaced or eliminated, for additional embodiments of the method. The order of the operations/processes may be interchangeable.

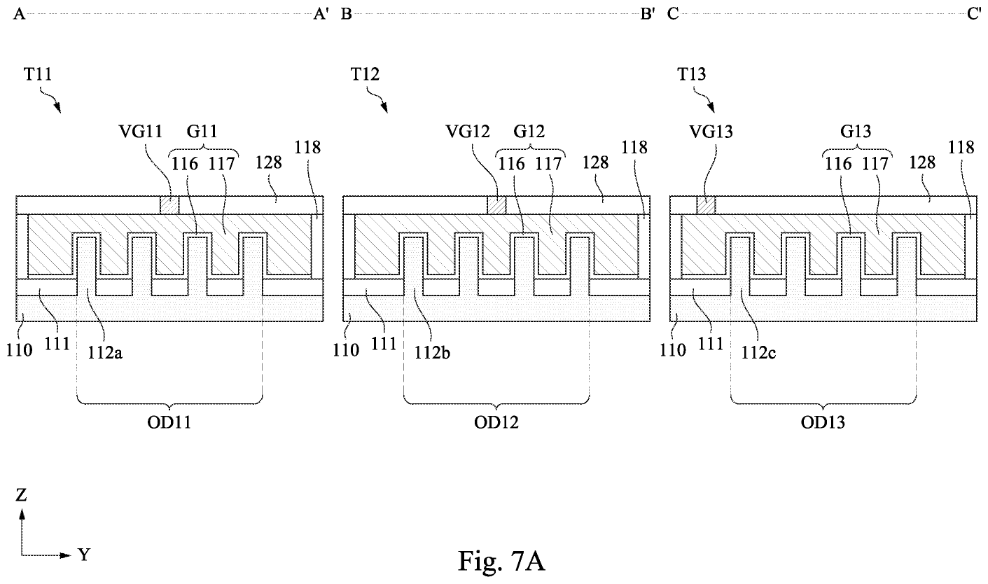

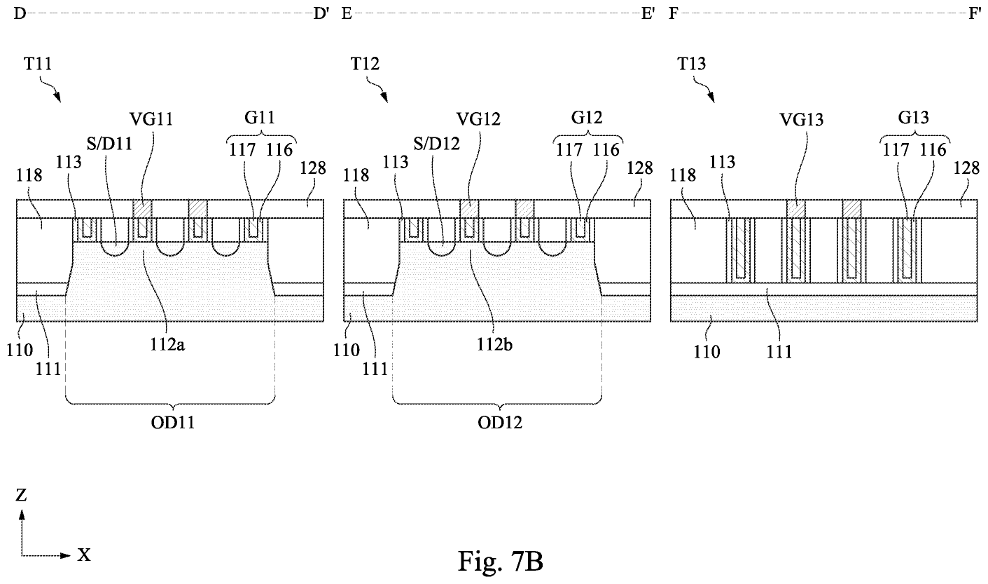

Reference is made to FIGS. 2A and 2B. One or more dielectric isolation structure 111 can formed in the substrate 110 to define the active regions OD11, OD12, and OD13. Formation of the dielectric isolation structure 111 includes, by way of example and not limitation, etching the substrate 110 to form one or more trenches that define the active regions OD11, OD12, and OD13, depositing one or more dielectric materials (e.g., silicon oxide) to overfill the trenches in the substrate 110, followed by a CMP process to planarize the one or more dielectric isolation structure 111 with the substrate 110. The dielectric isolation structure 111 can be further recessed (e.g., by an etch back process) to fall below the top surfaces of the active regions OD11, OD12, and OD13, such that the active regions OD11, OD12, and OD13 protrude above the top surface of the recessed dielectric isolation structure 111 to form fin-like structures. In some embodiments, the active region OD11 may be formed in the memory array region 101 of the memory system 100, and the active regions OD12 and OD13 may be formed in the peripheral circuit region 102. Thereafter, the transistor T11 (see FIGS. 7A and 7B) being of a memory device can be formed in the active region OD11, the transistor T12 (see FIGS. 7A and 7B) being of a sense amplifier and the transistor T13 (see FIGS. 7A and 7B) of a power header can be formed in the active regions OD12 and OD13.

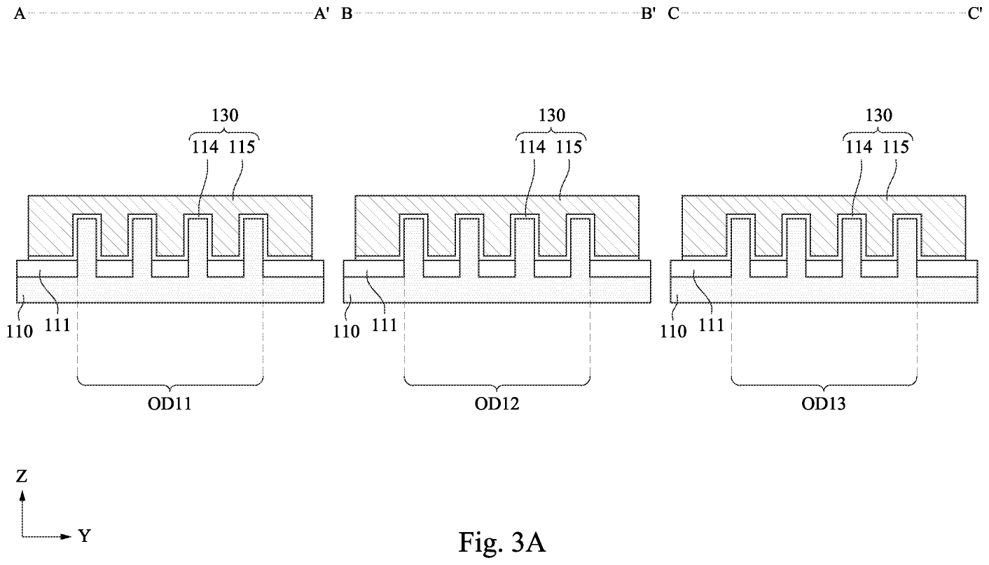

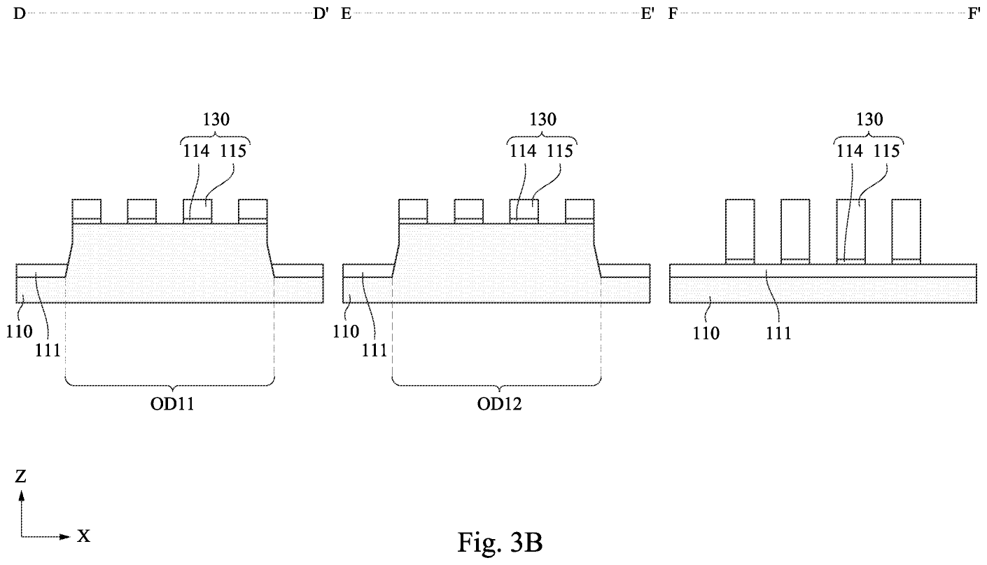

Reference is made to FIGS. 3A and 3B. After forming the one or more dielectric isolation structure 111, sacrificial gate structures 130 are formed over the active regions OD11, OD12, and OD13. The sacrificial gate structures 130 may include a sacrificial gate dielectric layer 114, and a sacrificial gate 115 over the sacrificial gate dielectric layer 114. In some embodiments, by way of example and not limitation, a sacrificial gate dielectric material (e.g., silicon oxide, silicon nitride, or the like) may be deposited over the substrate 110, a sacrificial gate material (e.g., doped or un-doped polysilicon) may be deposited over the dummy gate dielectric material and then planarized (e.g., by CMP), and the sacrificial gate material and sacrificial gate dielectric material are then patterned by using suitable photolithography and etching techniques, resulting in sacrificial gate structures 130 each including sacrificial gate dielectric material and sacrificial gate material to serve as its corresponding sacrificial gate dielectric layer 114 and sacrificial gate 115.

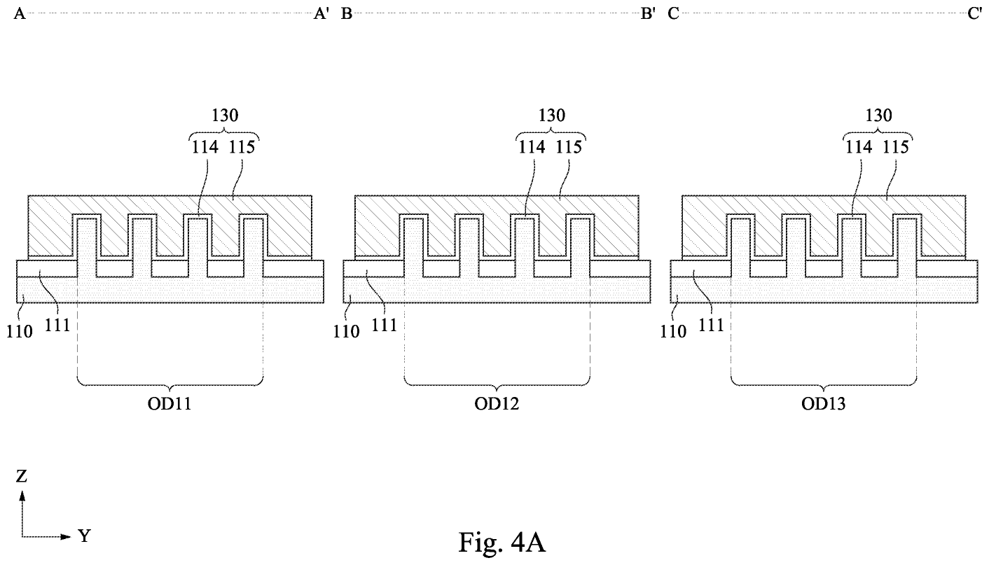

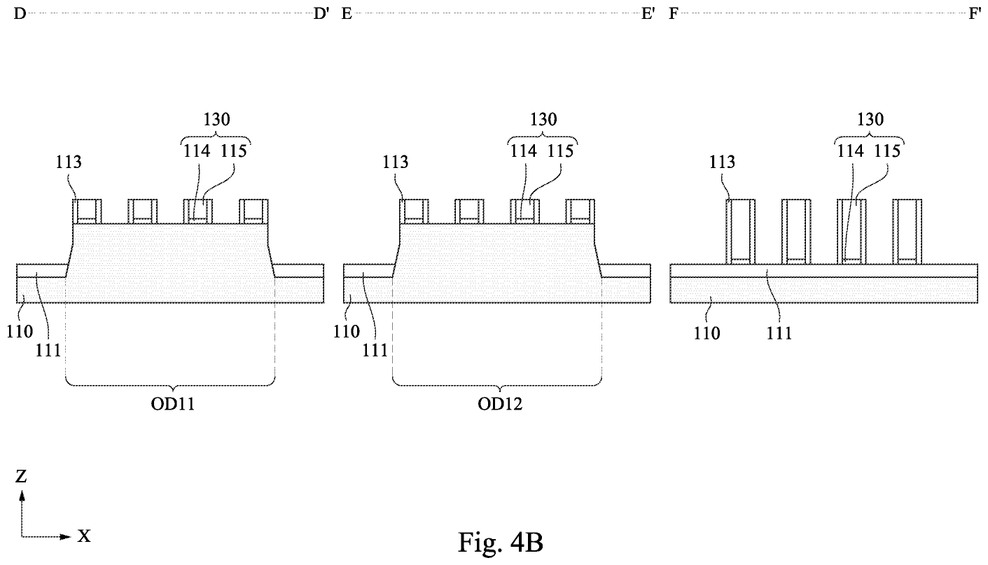

Reference is made to FIGS. 4A and 4B. Gate spacers 113 are then formed on opposite sidewalls of each sacrificial gate structure 130. In some embodiments, gate spacers 113 are formed by, for example, deposition and anisotropic etch of a spacer dielectric layer performed after the sacrificial gate patterning is complete. In some embodiments, the spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the sacrificial gate structures 130 while leaving the gate spacers 113 along the sidewalls of the sacrificial gate structures 130.

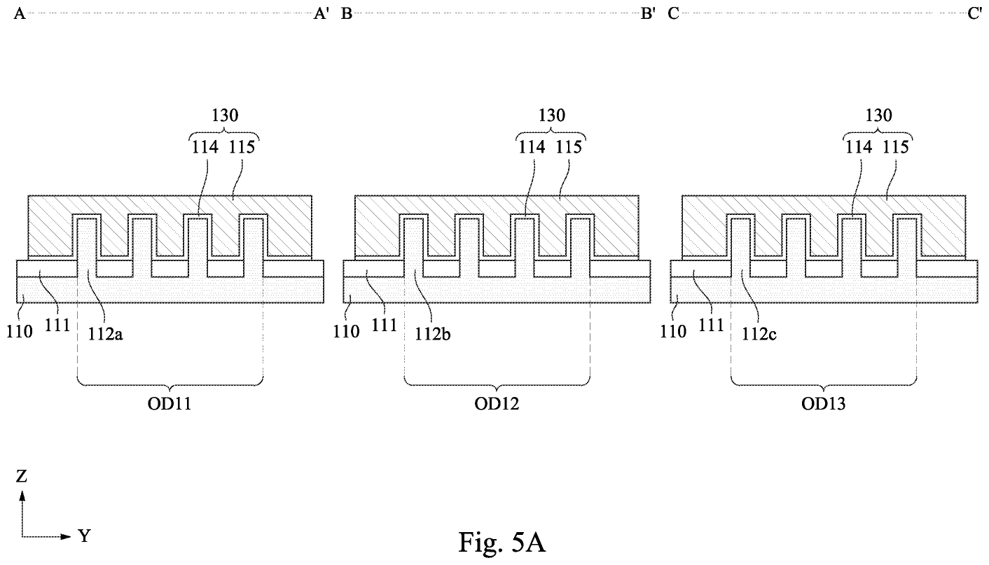

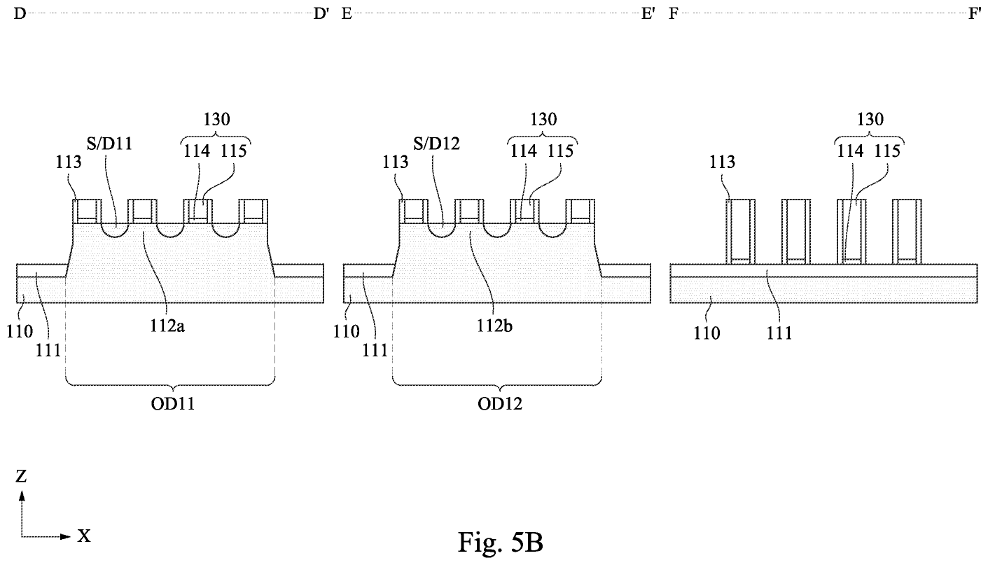

Reference is made to FIGS. 5A and 5B. After formation of the gate spacers 113, source/drain regions S/D11, S/D12, and S/D13 are formed in the active regions OD11, OD12, and OD13 and self-aligned to the gate spacers 113. A portion of the active regions OD11, OD12, and OD13 (i.e., fin-like structure) between the corresponding source/drain regions S/D11, S/D12, and S/D13 can serve as the channel regions 112a. 112b, and 112c. In some embodiments, the source/drain regions S/D11, S/D12, and S/D13 may include Ge, Si, GaAs, AlGaAs, SiGe, GaAsP, SiP, or other suitable material. The source/drain regions S/D11, S/D12, and S/D13 may be in-situ doped during the epitaxial process by introducing doping species including: p-type dopants, such as boron or BF₂; n-type dopants, such as phosphorus or arsenic; and/or other suitable dopants including combinations thereof. If the source/drain regions S/D11, S/D12, and S/D13 are not in-situ doped, an implantation process (i.e., a junction implant process) is performed to dope the source/drain regions S/D11, S/D12, and S/D13. In some exemplary embodiments, the source/drain regions S/D11, S/D12, and S/D13 in an n-type include Si: P. In some embodiments, the source/drain regions S/D11, S/D12, and S/D13 can be interchangeably referred to as source/drain regions, source/drain patterns, or source/drain structures.

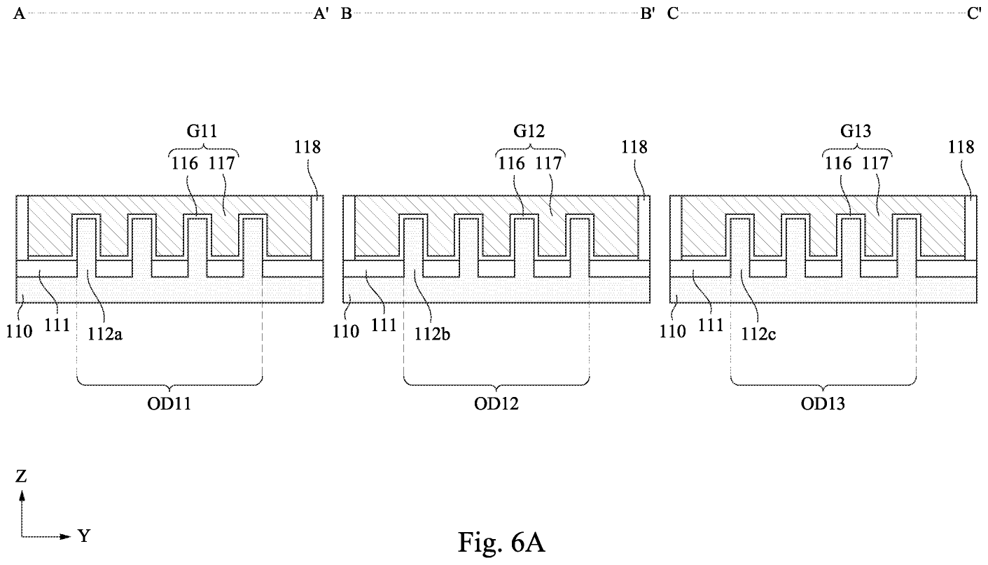

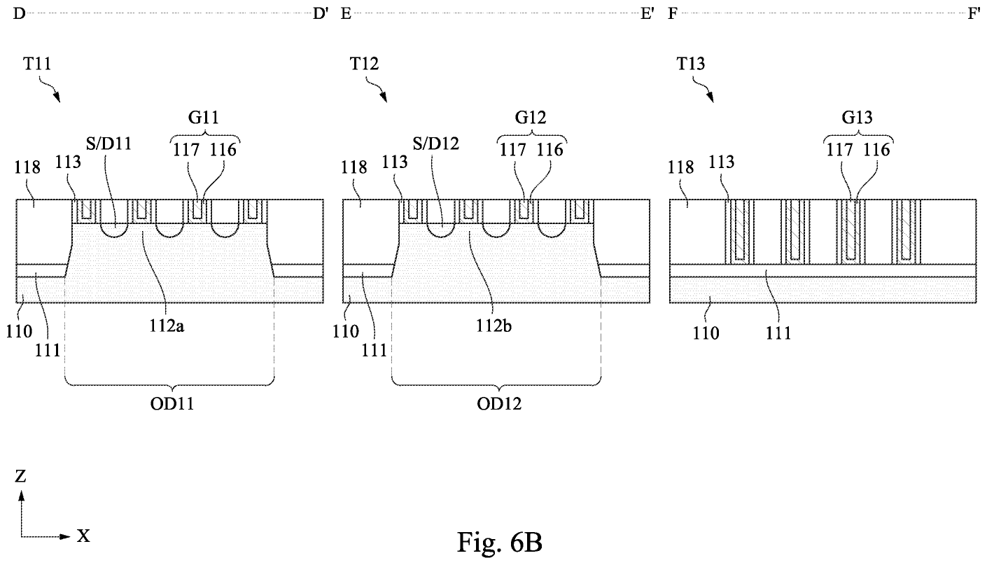

Reference is made to FIGS. 6A and 6B. The sacrificial gate structures 130 are replaced with the gate structures G11, G12, and G13. Fabrication of the source/drain regions S/D11, S/D12, and S/D13 and the gate structures G11, G12, and G13 of transistors can be referred to as a front-end-of-line (FEOL) processing. Specifically, an ILD layer 118 can be formed over the source/drain regions S/D11. S/D12, and S/D13 by depositing a dielectric material over the substrate 110, and then planarizing the dielectric material (e.g., by using CMP) until the sacrificial gate structures 130 are exposed. Subsequently, the gate replacement process includes, by way of example and not limitation, removing the sacrificial gate structures 130 using one or more etching techniques (e.g., dry etching, wet etching or combinations thereof), thereby creating gate trenches between respective gate spacers 113. Next, a gate dielectric layer 116 comprising one or more dielectrics, followed by a gate electrode layer 117 comprising one or more metals, are deposited to completely fill the gate trenches. Excess portions of the gate dielectric layer 116 and the gate electrode layer 117 are then removed from over the top surface of the ILD layer 118 using, for example, a CMP process. In some embodiments, the resulting structure, as illustrated in FIGS. 6A and 6B, may include remaining portions of the gate dielectric layer 116 and the gate electrode layer 117 inlaid between respective gate spacers 113 to serve as the gate structures G11, G12, and G13.

In some embodiments, the gate dielectric layer 116 includes a stack of an interfacial dielectric material and a high-k dielectric material. In some embodiments, the high-k gate dielectric materials include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), metal oxides, metal nitrides, metal silicates, transition metal-oxides, transition metal-nitrides, transition metal-silicates, oxynitrides of metals, metal aluminates, zirconium silicate, zirconium aluminate, zirconium oxide, titanium oxide, aluminum oxide, hafnium dioxide-alumina (HfO₂-Al₂O₃) alloy, other suitable high-k dielectric materials, and/or combinations thereof. The gate metal(s) is formed over the gate dielectric. Exemplary gate metal layer(s) 117 is a single layer structure or a multi-layer structure including, for example, copper (Cu), aluminum (Al), titanium (Ti), titanium nitride (TiN), tantalum (Ta), tantalum nitride (TaN), tantalum carbide (TaC), tantalum silicon nitride (TaSiN), tungsten (W), tungsten nitride (WN), molybdenum nitride (MoN), the like and/or combinations thereof. In some embodiments, the materials used in forming the gate structures G11, G12, and G13 may be deposited by any suitable method, e.g., CVD, PECVD, PVD, ALD, PEALD, electrochemical plating (ECP), electroless plating and/or the like. In some embodiments, the ILD layer 118 may include silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof.

Reference is made to FIGS. 7A and 7B. An ILD layer 128 can be formed over the gate structures G11, G12, and G13 by using suitable deposition techniques, and then the gate contacts VG11, VG12, and VG13 are formed in the ILD layer 128 and over the corresponding gate structures G11, G12, and G13. In some embodiments, the ILD layer 128 is formed of a same material as the ILD layer 128. After deposition of the ILD layer 128, the gate contacts VG11, VG12, and VG1 are formed by using photolithography, etching and deposition techniques. For example, in some embodiments, a patterned mask may be formed over the ILD layer 128 and used to etch contact openings that extend through the ILD layer 128 to expose the gate structures G11, G12, and G13. Thereafter, one or more metals (e.g., tungsten or copper) are deposited to fill the contact openings in the ILD layer 128 by using any acceptable deposition technique (e.g., CVD, ALD, PEALD, PECVD, PVD, ECP, electroless plating, or the like, or any combination thereof). Next, a planarization process (e.g., CMP) may be used to remove excess metals from above the top surface of the ILD layer 128. The resulting conductive plugs fill the contact openings in the ILD layer 128 and correspond to the gate contacts VG11, VG12, and VG1 making physical and electrical connections to the gate structures G11, G12, and G13.

A minimize leakage in the memory system 100 can be achieved by enhancing the threshold voltage of transistor T11 in the bit-cell 102 of the memory array region 101. Therefore, the transistor T11 can employ an NMOS transistor, with the gate contacts VG11 overlapping with the active region OD11 of the transistor T11. This configuration can increase the threshold voltage, hence reducing the current leakage. In addition, for the sense amplifier within the peripheral circuit region 102 as shown in FIG. 1A, an improved read window can be achieved by reduction of the threshold voltage of the transistor T12 as the sense amplifier. Therefore, the transistor T12 can employ a PMOS transistor, with the gate contacts VG12 overlapping with the active region OD12 of the transistor T12. This configuration can reduce the threshold voltage, thus expanding the read window and enhancing the sense amplifier's performance.

Moreover, for the power header within the peripheral circuit region 102 as shown in FIG. 1A, an efficient power utilization can be achieved by stability in the threshold voltage of the transistor T13 as the power header. Therefore, the transistor T13 can employ a NMOS transistor or a PMOS transistor, with the gate contacts VG13 non-overlapping with the active region OD13 of the transistor T13. This configuration can maintain a stable threshold voltage for the transistor T13, devoid of threshold voltage shifts, which contributes to an efficient power utilization within the memory system 100.

In some embodiments, the gate contacts VG11, VG12, and VG13 may include a metal-containing material such as titanium nitride, titanium oxide, tungsten, cobalt, ruthenium, aluminum, copper, combinations thereof, multi-layers thereof, or the like. In some embodiments, the ILD layer 128 may include silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or combinations thereof.

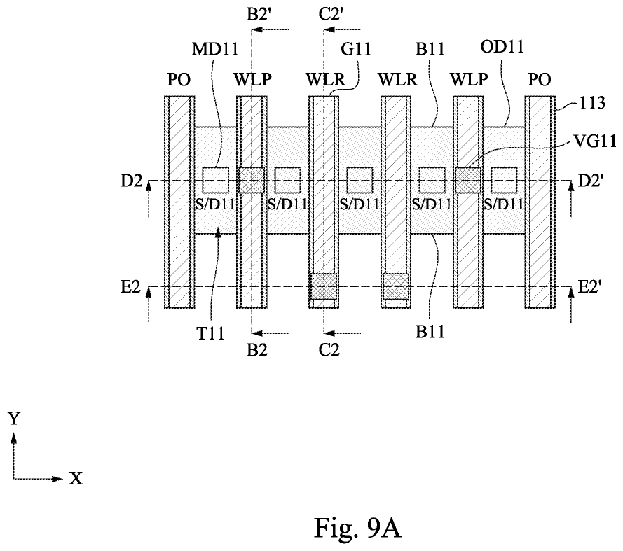

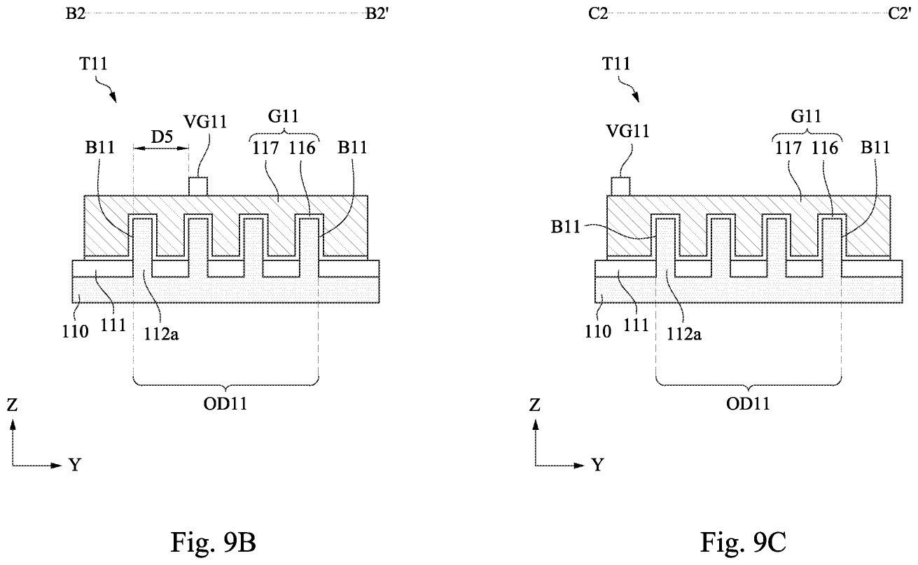

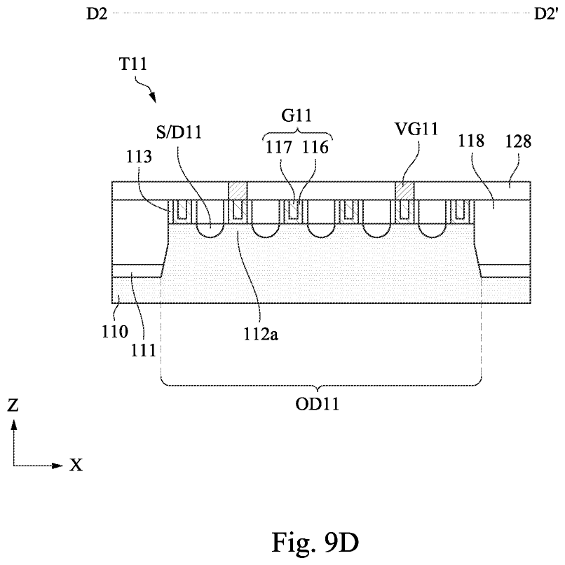

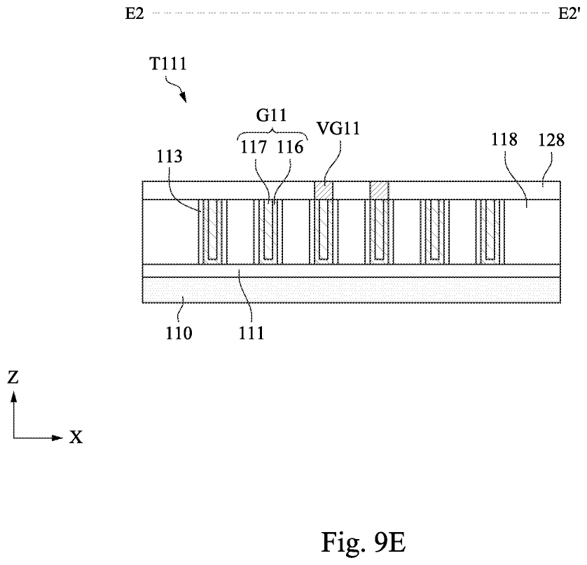

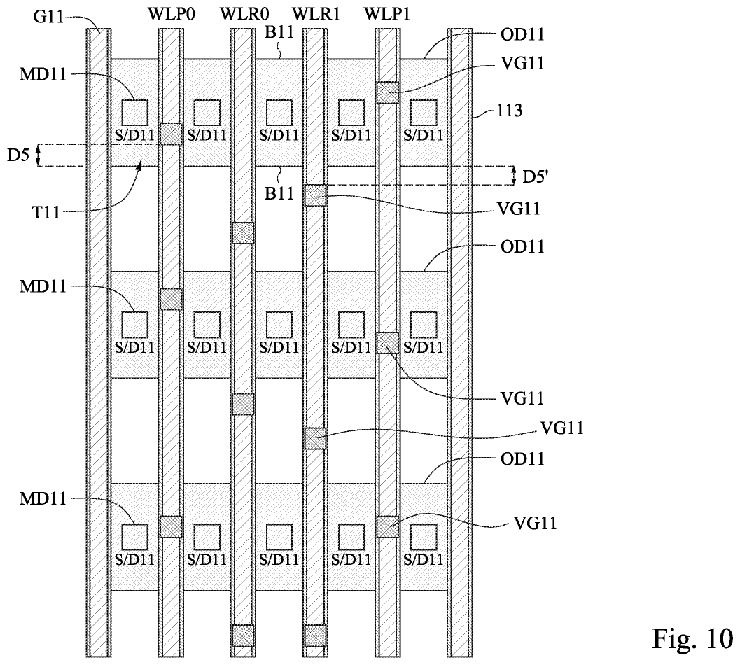

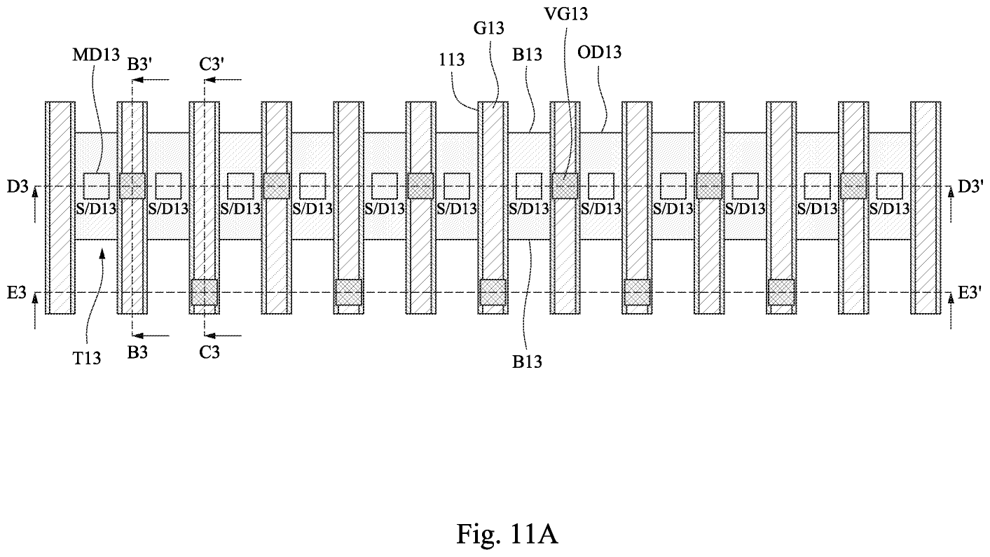

Reference is made to FIGS. 8A-10. FIG. 8A illustrates a circuit diagram of an anti-fuse memory cell in accordance with some embodiments of the present disclosure. FIGS. 8B-10 illustrate different views of a bit-cell 103a (see FIGS. 8B-8E), a bit-cell 103b (see FIGS. 9A-9E), a bit-cell 103c (see FIG. 10), and a bit-cell 103d (see FIG. 1B) in accordance with some embodiments of the present disclosure. In some embodiments, the bit-cell 103 shown in FIG. 1A can be replaced by the bit-cell 103a, 103b, 103c, and/or 103d. In some embodiments, the bit-cells 103a, 103b, and 103 shown in FIGS. 8B-10 may include, but are not limited to, anti-fuse memory cell. While FIGS. 8B-10 show embodiments of the bit-cells 103a, 103b, and 103c with different gate contact positions than the bit-cell 103 shown in FIGS. 1A-7B.

As shown in FIG. 8A, the circuit diagram of the anti-fuse memory cell is coupled to a program word line WLP, a read word line WLR, a source line SL, and a bit line BL. The anti-fuse memory cell may include a program transistor TP and a read transistor TR. Examples of the program transistor TP and/or the read transistor TR may include, but are not limited to, FinFET devices, nano-FET devices, and/or TFT devices. In some embodiment, the program transistor TP and the read transistor TR are identically configured. For example, the program transistor TP and the read transistor TR have the same size, and are manufactured by the same processes.

The program transistor TP may include a gate terminal 710 coupled to the program word line WLP, a first terminal 711 coupled to the source line SL, and a second terminal 712. The read transistor TR may include a gate terminal 720 coupled to the read word line WLR, a first terminal 721 coupled to the bit line BL, and a second terminal 722 coupled to the second terminal 712 of the program transistor TP. In other words, the program transistor TP and the read transistor TR are serially coupled with each other. In some embodiments, the first terminal 711 can be a source/drain region of the program transistor TP, and the second terminal 712 can be another source/drain region of the program transistor TP. The first terminal 721 can be a source/drain region of the read transistor TR, and the second terminal 722 can be another source/drain region of the read transistor TR. In some embodiments, the second terminal 712 of the program transistor TP and the second terminal 722 of the read transistor TR are the same, i.e., the program transistor TP and the read transistor TR share a common source/drain region.

In some embodiments, operations of the anti-fuse memory cell are controlled by a controller. The controller is coupled to the anti-fuse memory cell via the program word line WLP, the read word line WLR, the source line SL, and the bit line BL. When the anti-fuse memory cell is selected in a programming operation, the controller is configured to apply a higher voltage via the source line SL to the first terminal 711 of the program transistor TP, and apply a lower voltage via the program word line WLP to the gate terminal 710 of the program transistor TP. The controller is configured to turn off the read transistor TR in the programming operation. A voltage difference between the higher voltage on the first terminal 711 and the lower voltage on the gate terminal 710 is equal to or higher than the predetermined breakdown voltage that is sufficient to break down the gate dielectric layer of the program transistor TP. As a result, the gate dielectric layer of the program transistor TP is broken down, a programming current I_{prog} flows from the source line SL through the program transistor TP to the program word line WLP, and the anti-fuse memory cell is programmed. In some embodiments, a current l_{ower} with a voltage applied to the program word line WLP is a ground voltage, and the higher voltage applied to the source line SL is a program voltage.

When the anti-fuse memory cell is selected in a read operation, the controller is configured to apply a turn on voltage via the read word line WLR to the gate terminal 720 of the read transistor to turn on the read transistor TR. The controller is further configured to apply a read voltage via the source line SL and the program word line WLP correspondingly to the first terminal 711 and the gate terminal 710 of the program transistor TP to detect, while the read transistor TR is turned on, a datum stored in the anti-fuse memory cell. For example, the controller is configured to sense, e.g., by using the sense amplifier, a read current head flowing from the program transistor TP through the turned on read transistor TR to the bit line BL. A current value of the read current head when the anti-fuse memory cell has been previously programmed to store logic “0” is different from a current value of the read current when the anti-fuse memory cell has not been previously programmed and still stores logic “1.” By sensing the current value of the read current, the controller is configured to detect the datum stored in the anti-fuse memory cell.

Reference is made to FIGS. 8B-9E. FIGS. 8B and 9A illustrates top views of a semiconductor structure in accordance with some embodiments of the present disclosure. FIGS. 8C-8E illustrate cross-sectional views of the semiconductor structure obtained from reference cross-sections C1-C1′, D1-D1′, and E1-E1′ in FIG. 8B in accordance with some embodiments of the present disclosure. FIGS. 9B-9E illustrate cross-sectional views of the semiconductor structure obtained from reference cross-sections B2-B2′, C2-C2′, D2-D2′, and E2-E2′ in FIG. 9A in accordance with some embodiments of the present disclosure. While FIGS. 8A-9E shows embodiments of the semiconductor structures with different bit-cell configurations than the semiconductor structure in FIGS. 1A-1Q. In addition, the present disclosure may repeat reference numerals and/or letters in the various examples. This repetition is for the purpose of simplicity and clarity and does not in itself dictate a relationship between the various embodiments and/or configurations discussed. The semiconductor structure is a non-limiting example for facilitating the illustration of the present disclosure.

As shown in FIGS. 8B-9E, the gate structures G11 connected to the program word line WLP can be interchangeably referred to as a program transistor, and the gate structures G11 connected to the read word line WLR can be interchangeably referred to as a read transistor. In some embodiments, a minimize leakage in the memory system can be achieved by enhancing the threshold voltage of transistor T11 connected to the program word line WLP. Therefore, the transistor T11 connected to the program word line WLP can employ NMOS transistors, with the gate contacts VG11 overlapping with the active region OD11 of the transistor T11 connected to the program word line WLP. This configuration can increase the threshold voltage, hence reducing the current leakage. In addition, the transistor T11 connected to the read word line WLR can also employ NMOS transistors, with the gate contacts VG11 (see FIGS. 8B-8E) overlapping with the active region OD11 of the transistor T11 connected to the read word line WLR. In some embodiment, the transistor T11 connected to the read word line WLR can also employ NMOS transistors, with the gate contacts VG11 (see FIGS. 9A-9E) non-overlapping with the active region OD11 of the transistor T11 connected to the read word line WLR.

Reference is made to FIG. 10. FIG. 10 illustrates a top view of semiconductor structure in accordance with some embodiments of the present disclosure. While FIG. 10 show an embodiment of the semiconductor structure with a different configuration than the semiconductor structure in FIGS. 8B-9E. In addition, the present disclosure may repeat reference numerals and/or letters in the various examples. This repetition is for the purpose of simplicity and clarity and does not in itself dictate a relationship between the various embodiments and/or configurations discussed. The semiconductor structure is a non-limiting example for facilitating the illustration of the present disclosure.

As shown in FIG. 10, the gate structures G11 can be extend to across a plurality of the active regions OD11. In some embodiments, a minimize leakage in the memory system can be achieved by enhancing the threshold voltage of transistor T11 (i.e., program transistor) connected to the program word line WLP. Therefore, the transistor T11 connected to the program word line WLP can employ NMOS transistors, with the gate contacts VG11 overlapping with the active region OD11 of the transistor T11 connected to the program word line WLP. This configuration can increase the threshold voltage, hence reducing the current leakage. In some embodiments, the gate contact VG11 on the program transistor can spaced apart from the edge B11 of the active regions OD11 by at least a lateral distance D5. By way of example and not limitation, the distance D5 may be greater than about 5 nm, such as about 5, 6, 7, 8, 9, 10, 11, 12, 13, 14, or 15 nm. In addition, the transistor T11 (i.e., read transistor) connected to the read word line WLR can also employ NMOS transistors, with the gate contacts VG11 non-overlapping with the active region OD11 of the transistor T11 connected to the read word line WLR, such that the gate contacts VG11 can be located between the adjacent two of the read transistors. In some embodiments, the gate contact VG11 on the read transistor can spaced apart from the edge B11 of the active regions OD11 by at least a lateral distance D5′. By way of example and not limitation, the distance D5′ may be greater than about 15 nm, such as about 15, 16, 17, 18, 19, 20, 21, 22, 23, 24, or 25 nm. In some embodiments, the distance D5′ can be greater than the distance D5.

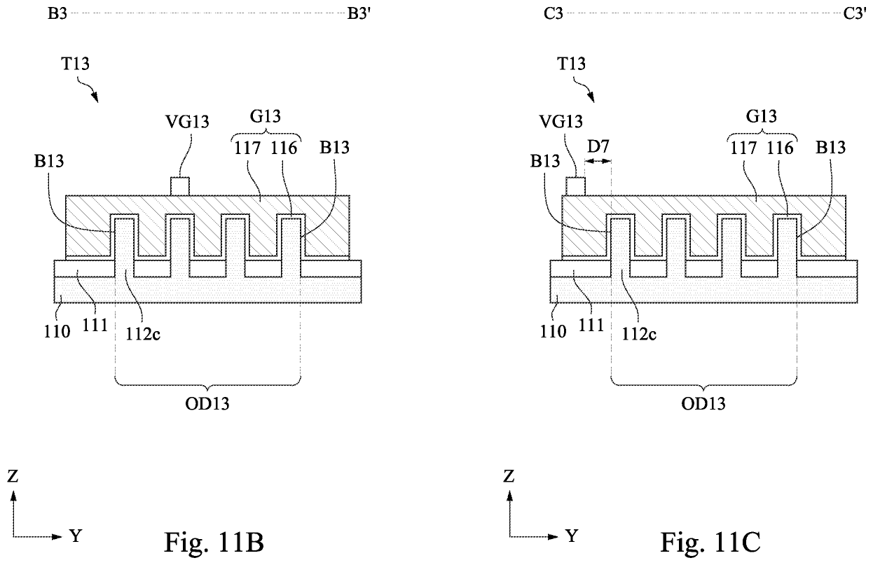

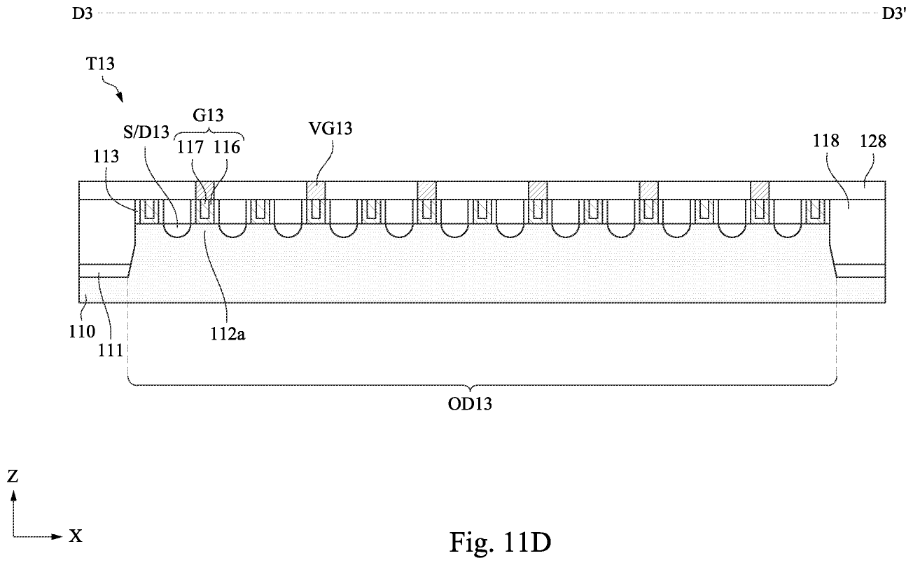

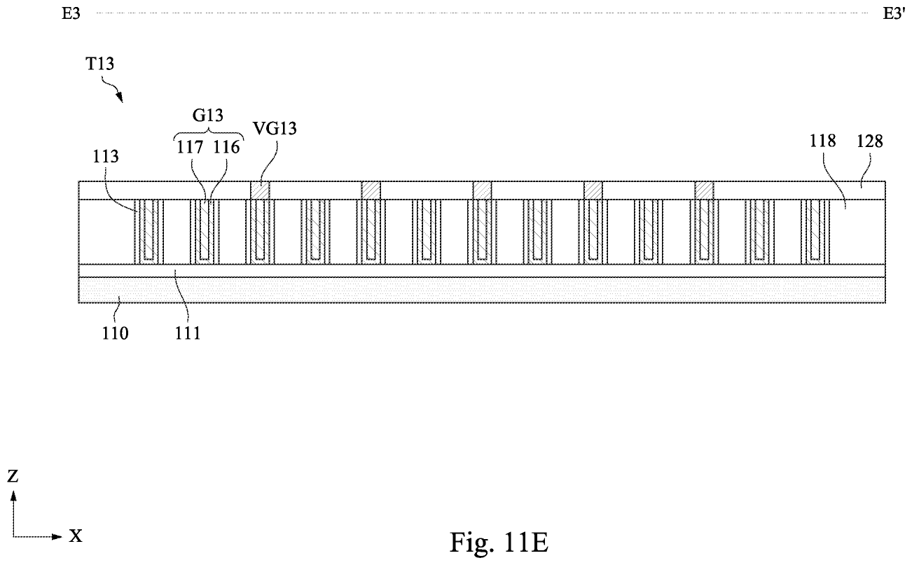

Reference is made to FIGS. 11A-14. FIGS. 11A-14 illustrate different views of semiconductor structures including transistors (e.g., sense amplifier transistors and power header transistors) in peripheral regions of memory systems in accordance with some embodiments of the present disclosure. Examples of the transistors in peripheral region may include, but are not limited to, FinFET devices, nano-FET devices, and/or TFT devices. FIGS. 11A and 12-14 illustrate top views of semiconductor structures in accordance with some embodiments of the present disclosure. FIGS. 11B-11E illustrate cross-sectional views of the semiconductor structure obtained from reference cross-sections B3-B3′, C3-C3′, D3-D3′, and E3-E3′ in FIG. 11A in accordance with some embodiments of the present disclosure. While FIGS. 11A-14 show embodiments of the semiconductor structures with a different gate contact configurations than the semiconductor structure in FIG. 1A. In addition, the present disclosure may repeat reference numerals and/or letters in the various examples. This repetition is for the purpose of simplicity and clarity and does not in itself dictate a relationship between the various embodiments and/or configurations discussed. The semiconductor structure is a non-limiting example for facilitating the illustration of the present disclosure.

In some embodiments, the semiconductor structure in the peripheral circuit region 102 as shown in FIG. 1A can be replaced by the semiconductor structures as shown in FIGS. 11A-14. In some embodiments, the semiconductor structures including the transistors T13 can function as a power header. As illustrated in FIGS. 11A-11E, there is an intermittent pattern to how gate contacts VG13 interact with the active region OD13. Some gate contacts VG13 periodically overlap or cover the active region OD13, while others are positioned intermittently outside this active region OD13. In some embodiments, when the gate contact VG13 of the transistor T13 is positioned such that it overlaps with the active region OD13, the resulting threshold voltage (Vt) can be at about −10 mV. When the gate contact VG13 is positioned such that it does not overlap with the active region OD13, the resulting threshold voltage (Vt) is at about 0 mV. Considering these two cases, it is indicated that the overall threshold voltage, Vt, settles at an average of the two individual cases. That is, the overall threshold voltage Vt can stand at about −5 mV. Therefore, this dynamic offers valuable insights into the device's operating conditions and can influence the strategic placement of the gate contact VG13 relative to the active region OD13.

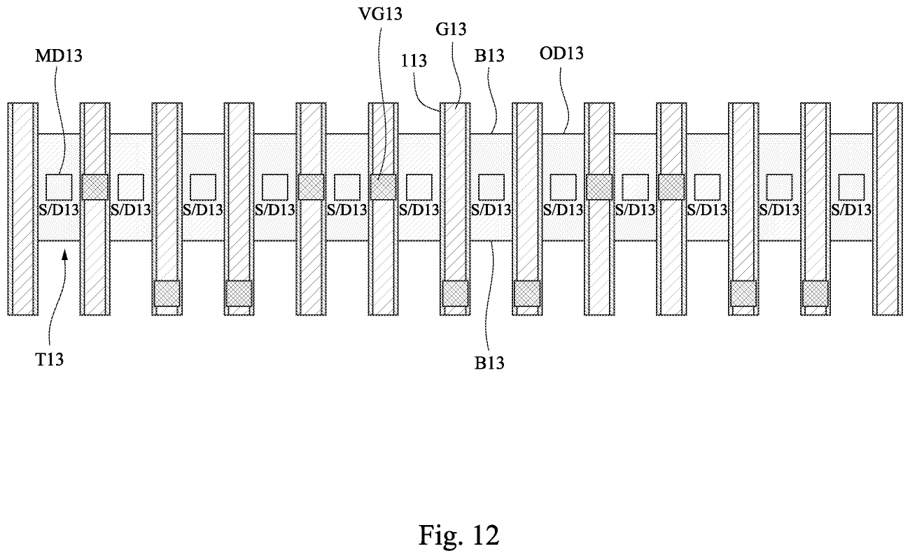

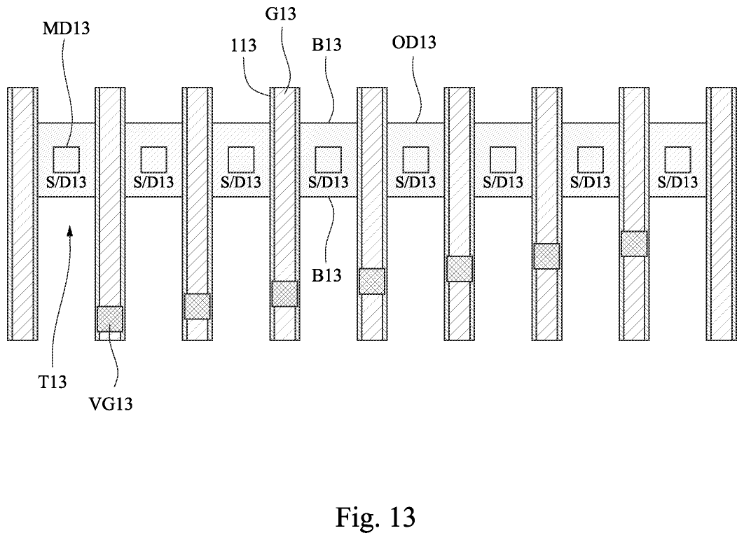

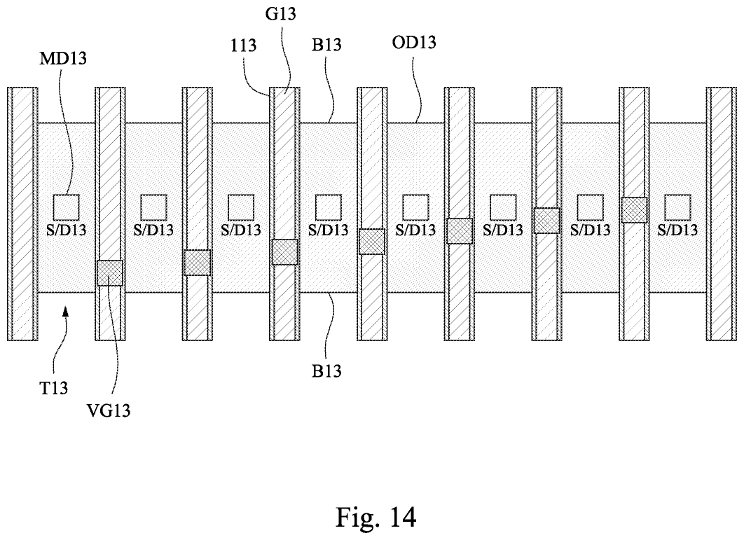

FIG. 12 illustrates a variation on this design, with the primary distinction from FIGS. 11A-11E being the arrangement of gate contacts VG13. At least two adjacent gate contacts VG13 cover the active region OD13, followed by a sequence of at least two adjacent gate contacts VG13 situated outside the active region OD13. FIG. 13 illustrates a variant where all gate contacts VG13 can be situated externally to the active region OD13. These gate contacts VG13 can exhibit a dynamic positioning, as they gradually draw closer to or recede from the edge B13 of the active region OD13. In some embodiments, the maximum distance between the gate contact VG13 and the edge of the active region OD13 can be constrained to not exceed 50 nm, while the minimum distance is no less than 19 nm. FIG. 14 illustrates a variant where all gate contacts VG13 can be situated overlying the active region OD13. These gate contacts VG13 can exhibit a dynamic positioning, as they gradually draw closer to or recede from the edge B13 of the active region OD13. In some embodiments, the maximum distance from the edge can be constrained to not exceed 11 nm. Overall, these different configurations of gate contacts relative to the active regions OD13 can exhibit the versatility of design and optimization possibilities in the peripheral circuit region 102, offering scope for tailoring the performance characteristics of the transistors (e.g., power header transistors) to meet specific requirements.

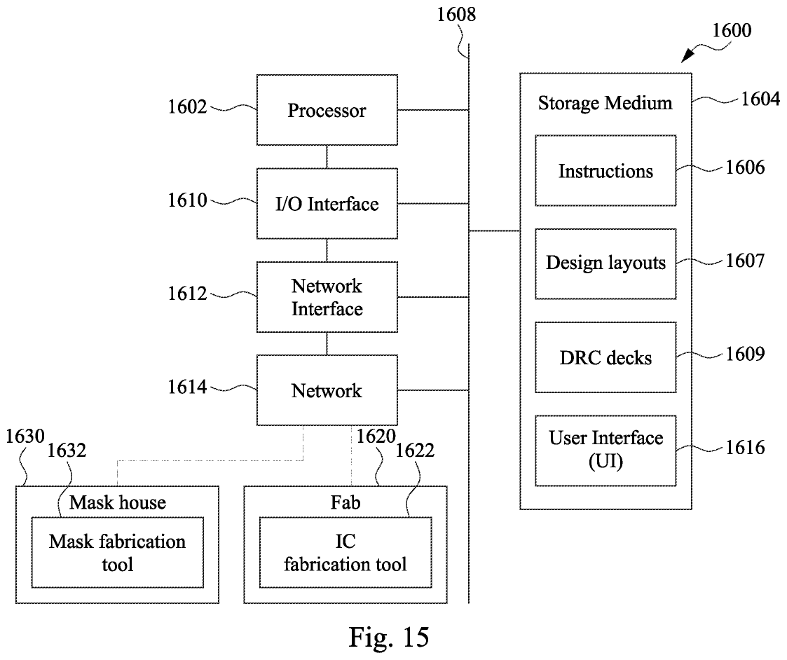

FIG. 15 is a schematic diagram of an electronic design automation (EDA) system 1600, in accordance with some embodiments. Methods described herein of generating design layouts, e.g., layouts of the integrated circuits 10, 20, 30, 40, 50, 60, 70, 80, 90, 1000, 1100, 1200, 1300, 1400 and/or 1500 with resistor circuits as discussed above, in accordance with one or more embodiments, are implementable, for example, using EDA system 1600, in accordance with some embodiments. At least integrated circuit 10, 20, 30, 40, 50, 60, 70, 80, 90, 1000, 1100, 1200, 1300, 1400 and/or 1500 is manufactured by a corresponding layout design similar to the corresponding integrated circuit. For brevity FIGS. 1A-14 are described as corresponding integrated circuits, but in some embodiments, FIGS. 1A-14 also correspond to layout designs with corresponding patterns similar to integrated circuit 10, 20, 30, 40, 50, 60, 70, 80, 90, 1000, 1100, 1200, 1300, 1400 and/or 1500 with corresponding structures, and pattern relationships including alignment, lengths and widths, as well as configurations and layers of a corresponding layout design are similar to the structural relationships and configurations and layers of the corresponding integrated circuit, and similar detailed description will not be described for brevity. In some embodiments, EDA system 1600 is a computing device that is capable of executing one or more automatic placement & routing (APR) operations. The EDA system 1600 including a hardware processor 1602 and a non-transitory, computer-readable storage medium 1604. Computer-readable storage medium 1604, amongst other things, is encoded with, i.e., stores, a set of executable instructions 1606, design layouts 1607, design rule check (DRC) decks 1609 or any intermediate data for executing the set of instructions. Each design layout 1607 may include a graphical representation of an integrated chip, such as for example, a GSII file. Each DRC deck 1609 may include a list of design rules specific to a semiconductor process chosen for fabrication of a design layout 1607. Execution of instructions 1606, design layouts 1607 and DRC decks 1609 by hardware processor 1602 represents (at least in part) an EDA tool which implements a portion or all of, e.g., the methods described herein in accordance with one or more (hereinafter, the noted processes and/or methods).

Processor 1602 is electrically coupled to computer-readable storage medium 1604 via a bus 1608. Processor 1602 is also electrically coupled to an I/O interface 1610 by bus 1608. A network interface 1612 is also electrically connected to processor 1602 via bus 1608. Network interface 1612 is connected to a network 1614, so that processor 1602 and computer-readable storage medium 1604 are capable of connecting to external elements via network 1614. Processor 1602 is configured to execute instructions 1606 encoded in computer-readable storage medium 1604 in order to cause EDA system 1600 to be usable for performing a portion or all of the noted processes and/or methods. In one or more embodiments, processor 1602 is a central processing unit (CPU), a multi-processor, a distributed processing system, an application specific integrated circuit (ASIC), and/or a suitable processing unit.

In one or more embodiments, computer-readable storage medium 1604 is an electronic, magnetic, optical, electromagnetic, infrared, and/or a semiconductor system (or apparatus or device). For example, computer-readable storage medium 1604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1604 includes a compact disk-read only memory (CD-ROM), a compact disk-read/write (CD-R/W), and/or a digital video disc (DVD).

In one or more embodiments, computer-readable storage medium 1604 stores instructions 1606, design layouts 1607 (e.g., layouts of the integrated circuits 10, 20, 30, 40, 50, 60, 70, 80, 90, 1000, 1100, 1200, 1300, 1400 and/or 1500 with resistor circuits as discussed previously) and DRC decks 1609 configured to cause EDA system 1600 (where such execution represents (at least in part) the EDA tool) to be usable for performing a portion or all of the noted processes and/or methods. In one or more embodiments, storage medium 1604 also stores information which facilitates performing a portion or all of the noted processes and/or methods.

EDA system 1600 includes I/O interface 1610. I/O interface 1610 is coupled to external circuitry. In one or more embodiments, I/O interface 1610 includes a keyboard, keypad, mouse, trackball, trackpad, touchscreen, and/or cursor direction keys for communicating information and commands to processor 1602.

EDA system 1600 also includes network interface 1612 coupled to processor 1602. Network interface 1612 allows EDA system 1600 to communicate with network 1614, to which one or more other computer systems are connected. Network interface 1612 includes wireless network interfaces such as BLUETOOTH, WIFI, WIMAX, GPRS, or WCDMA; or wired network interfaces such as ETHERNET, USB, or IEEE-1388. In one or more embodiments, a portion or all of noted processes and/or methods, is implemented in two or more EDA systems 1600.

EDA system 1600 is configured to receive information through I/O interface 1610. The information received through I/O interface 1610 includes one or more of instructions, data, design rules, libraries of standard cells, and/or other parameters for processing by processor 1602. The information is transferred to processor 1602 via bus 1608. EDA system 1600 is configured to receive information related to a user interface (UI) 1616 through I/O interface 1610. The information is stored in computer-readable medium 1604 as UI 1616.

Also illustrated in FIG. 15 are fabrication tools associated with the EDA system 1600. For example, a mask house 1630 receives a design layout from the EDA system 1600 by, for example, the network 1614, and the mask house 1630 has a mask fabrication tool 1632 (e.g., a mask writer) for fabricating one or more photomasks (e.g., photomasks used for fabricating integrated circuits 10, 20, 30, 40, 50, 60, 70, 80, 90, 1000, 1100, 1200, 1300, 1400 and/or 1500 with resistor circuits as discussed above) based on the design layout generated from the EDA system 1600. An IC fabricator (“Fab”) 1620 may be connected to the mask house 1630 and the EDA system 1600 by, for example, the network 1614. Fab 1620 includes an IC fabrication tool 1622 for fabricating IC chips (e.g., layouts of the integrated circuits 10, 20, 30, 40, 50, 60, 70, 80, 90, 1000, 1100, 1200, 1300, 1400 and/or 1500 with resistor circuits as discussed above) using the photomasks fabricated by the mask house 1630. By way of example and not limitation, the IC fabrication tool 1622 includes one or more cluster tools for fabricating IC chips. The cluster tool may be a multiple reaction chamber type composite equipment which includes a polyhedral transfer chamber with a wafer handling robot inserted at the center thereof, a plurality of process chambers (e.g., CVD chamber, PVD chamber, etching chamber, annealing chamber or the like) positioned at each wall face of the polyhedral transfer chamber; and a loadlock chamber installed at a different wall face of the transfer chamber.

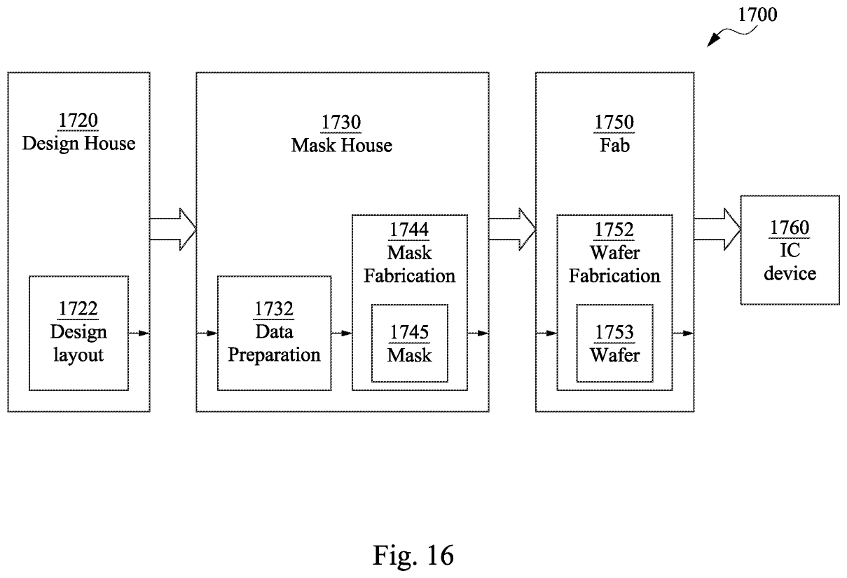

FIG. 16 is a block diagram of an IC manufacturing system 1700, and an IC manufacturing flow associated therewith, in accordance with some embodiments. In some embodiments, based on one or more design layouts, e.g., layouts of the integrated circuits 10, 20, 30, 40, 50, 60, 70, 80, 90, 1000, 1100, 1200, 1300, 1400 and/or 1500 with resistor circuits as discussed above, one or more photomasks and one or more integrated circuits are fabricated using manufacturing system 1700.

In FIG. 16, an IC manufacturing system 1700 includes entities, such as a design house 1720, a mask house 1730, and a Fab 1750, that interact with one another in the design, development, and manufacturing cycles and/or services related to manufacturing ICs 1760. The entities in IC manufacturing system 1700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1720, mask house 1730, and Fab 1750 is owned by a single larger company. In some embodiments, two or more of design house 1720, mask house 1730, and Fab 1750 coexist in a common facility and use common resources.

Design house (or design team) 1720 generates design layouts 1722 (e.g., layouts of the integrated circuits 10, 20, 30, 40, 50, 60, 70, 80, 90, 1000, 1100, 1200, 1300, 1400 and/or 1500 with resistor circuits as discussed above). Design layouts 1722 include various geometrical patterns designed for ICs 1760 (e.g., integrated circuits 10, 20, 30, 40, 50, 60, 70, 80, 90, 1000, 1100, 1200, 1300, 1400 and/or 1500 with resistor circuits as discussed above). The geometrical patterns correspond to patterns of metal, oxide, or semiconductor layers that make up the various components of ICs 1760 to be fabricated. The various layers combine to form various device features. For example, a portion of design layout 1722 includes various circuit features, such as active regions, passive regions, functional gate structures, resistor structures, gate contacts, resistor contacts, source/drain contacts, and/or metal lines, to be formed on a semiconductor wafer. Design house 1720 implements a proper design procedure to form design layout 1722. The design procedure includes one or more of logic design, physical design or place and route. Design layout 1722 is presented in one or more data files having information of the geometrical patterns and a netlist of various nets. For example, design layout 1722 can be expressed in a GDSII file format or DFII file format.

Mask house 1730 includes data preparation 1732 and mask fabrication 1744. Mask house 1730 uses design layout 1722 (e.g., layout of the integrated circuit 10, 20, 30, 40, 50, 60, 70, 80, 90, 1000, 1100, 1200, 1300, 1400 or 1500 as discussed above) to manufacture one or more photomasks 1745 to be used for fabricating the various layers of IC 1760 according to design layout 1722. Mask house 1730 performs mask data preparation 1732, where design layout 1722 is translated into a representative data file (“RDF”). Mask data preparation 1732 provides the RDF to mask fabrication 1744. Mask fabrication 1744 includes a mask writer. A mask writer converts the RDF to an image on a substrate, such as a photomask (reticle) 1745. Design layout 1722 is manipulated by mask data preparation 1732 to comply with particular characteristics of the mask writer and/or rules of fab 1750. In FIG. 16, mask data preparation 1732 and mask fabrication 1744 are illustrated as separate elements. In some embodiments, mask data preparation 1732 and mask fabrication 1744 can be collectively referred to as mask data preparation.

In some embodiments, mask data preparation 1732 includes optical proximity correction (OPC) which uses lithography enhancement techniques to compensate for image errors, such as those that can arise from diffraction, interference, other process effects and the like. OPC adjusts design layout 1722. In some embodiments, mask data preparation 1732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1732 includes a mask rule checker (MRC) that checks design layout 1722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies design layout 1722 diagram to compensate for limitations during mask fabrication 1744, which may undo part of the modifications performed by OPC in order to meet mask creation rules.

In some embodiments, mask data preparation 1732 includes lithography process checking (LPC) that simulates processing that will be implemented by Fab 1750 to fabricate ICs 1760. LPC simulates this processing based on design layout 1722 to create a simulated manufactured integrated circuit, such as IC 1760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine design layout 1722.

After mask data preparation 1732 and during mask fabrication 1744, a photomask 1745 or a group of photomasks 1745 are fabricated based on the design layout 1722. In some embodiments, mask fabrication 1744 includes performing one or more lithographic exposures based on the design layout 1722. In some embodiments, an electron-beam (e-beam) or a mechanism of multiple e-beams is used to form a pattern on a photomask 1745 based on design layout 1722. Photomask 1745 can be formed in various technologies. In some embodiments, photomask 1745 is formed using binary technology. In some embodiments, a mask pattern includes opaque regions and transparent regions. A radiation beam, such as an ultraviolet (UV) beam, used to expose the radiation sensitive material layer (e.g., photoresist) which has been coated on a wafer, is blocked by the opaque regions and transmits through the transparent regions. In one example, a binary mask version of photomask 1745 includes a transparent substrate (e.g., fused quartz) and an opaque material (e.g., chromium) coated in the opaque regions of the binary mask. In another example, photomask 1745 is formed using a phase shift technology. In a phase shift mask (PSM) version of photomask 1745, various features in the pattern formed on the phase shift photomask are configured to have proper phase difference to enhance the resolution and imaging quality. In various examples, the phase shift photomask can be attenuated PSM or alternating PSM. The photomask(s) generated by mask fabrication 1744 is used in a variety of processes. For example, such a mask(s) is used in an ion implantation process to form various doped regions in semiconductor wafer 1753, in an etching process to form various etching regions in semiconductor wafer 1753, and/or in other suitable processes.

Fab 1750 may include wafer fabrication 1752. Fab 1750 is an IC fabrication business that includes one or more manufacturing facilities for the fabrication of a variety of different IC products. In some embodiments, Fab 1750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (BEOL fabrication), and a third manufacturing facility may provide other services for the foundry business.

Fab 1750 uses photomask(s) 1745 fabricated by mask house 1730 to fabricate ICs 1760. Thus, fab 1750 at least indirectly uses design layout(s) 1722 (e.g., layouts of the integrated circuits 10, 20, 30, 40, 50, 60, 70, 80, 90, 1000, 1100, 1200, 1300, 1400 and/or 1500 with resistor circuits as discussed above) to fabricate ICs 1760. In some embodiments, wafer 1753 is processed by fab 1750 using photomask(s) 1745 to form ICs 1760. In some embodiments, the device fabrication includes performing one or more photolithographic exposures based at least indirectly on design layout 1722.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a flexibility of gate contact placement within a memory bit-cell and some peripheral devices. For example, in the NMOS memory cell, the gate contact can be positioned inside the active region from the top view. Alternatively, this disclosure can allow for the implementation of a 3D stack of IGZO TFT devices. This configuration can provide an increased threshold voltage shift, enabling a boost in the cell current or a reduction in cell leakage. In addition, for the peripheral sense amplifier (e.g., including PMOS transistor), the gate contact can be positioned inside the active region from the top view. This configuration can provide a reduced threshold voltage shift, thus expanding the read window and enhancing the sense amplifier's performance. Furthermore, for power header (e.g., including PMOS/NMOS transistor), the gate contact can be positioned outside the active region from the top view. This configuration can provide stability in the threshold voltage, thus contributing to efficient power utilization within the memory system.

In some embodiments, a method includes forming a first gate structure across a first active region on a substrate within a memory region, wherein the first gate structure is of a first transistor being of a first conductivity type; forming a second gate structure across a second active region on the substrate within a peripheral region, wherein the second gate structure is of a second transistor being of a second conductivity type, the second conductivity type is opposite to the first conductivity type; forming a first gate contact over the first gate structure, the first gate contact overlapping with the first active region; forming a second gate contact over the second gate structure, the second gate contact non-overlapping with the second active region. In some embodiments, the first transistor is of an n-channel metal-oxide-semiconductor transistor. In some embodiments, from a top view, the first gate contact is laterally spaced apart from an edge of the first active region by a distance at least about 10 nm. In some embodiments, the method further includes forming a third gate structure across the first active region within the memory region, the third gate structure is of a third transistor, the third transistor forming an anti-fuse memory cell with the first transistor, the third gate structure electrically connected to a read word line, and the first gate structure electrically connected to a program word line; forming a third gate contact over the third gate structure, the third gate contact non-overlapping with the first active region. In some embodiments, the first transistor is a thin film transistor, the thin film transistor comprising a gate layer, a high-k dielectric layer over the gate layer, an indium gallium zinc oxide layer over the high-k dielectric layer, and a plurality of titanium nitride layers on opposite sides of the indium gallium zinc oxide layer. In some embodiments, the second transistor is of a p-channel metal-oxide-semiconductor transistor. In some embodiments, from a top view, the second gate contact is laterally spaced apart from an edge of the second active region by a distance at least about 15 nm. In some embodiments, the memory region is at a higher position than the peripheral region. In some embodiments, the method further includes forming a third gate structure across a third active region within the peripheral region over the substrate, wherein the third gate structure is of a third transistor being of the second conductivity type; forming a third gate contact over the third gate structure, the third gate contact overlapping with the third active region. In some embodiments, the second transistor is of a power header transistor, and the third transistor is of a sense amplifier transistor.

In some embodiments, a method includes forming a plurality of fin structures upwardly extending from a semiconductor substrate within a memory bit-cell; forming a first gate strip extending across the fin structures, and a second gate strip extending across the fin structures; growing a plurality of source/drain structures on the fin structures; forming a first gate contact over the first gate strip, wherein from a top view, the first gate contact is positioned within a region bordered by a first outer edge of a first outermost one of the fin structures and a second outer edge of a second outermost one of the fin structures opposite to the first outer edge; forming a second gate contact over the second gate strip, wherein from the top view, the second gate contact is positioned outside of the region bordered by the first and second outer edges of the first and second outermost ones of the fin structures. In some embodiments, the first gate strip is electrically connected to a read word line through the first gate contact, and the second gate strip is electrically connected to a program word line through the second gate contact. In some embodiments, the first gate strip is of a first n-type metal-oxide-semiconductor (NMOS) device, and the second gate strip is of a second NMOS device. In some embodiments, from the top view, the second gate contact is spaced apart from the region by a non-zero distance. In some embodiments, the method further includes forming a third gate strip extending across the fin structures and between the first and second gate strips; forming a third gate contact over the third gate strip, wherein from the top view, the second gate contact is positioned outside of the region bordered by the first and second outer edges of the first and second outermost ones of the fin structures. In some embodiments, the method further includes forming a third gate strip extending across the fin structures, wherein the second gate strip is between the first and third gate strips; forming a third gate contact over the third gate strip, wherein from the top view, the second gate contact is positioned within the region bordered by the first and second outer edges of the first and second outermost ones of the fin structures.

In some embodiments, the semiconductor structure includes a substrate, a first transistor, a second transistor, and a first gate contact. The first transistor is over the substrate. The first transistor is of a sense amplifier or a power header of a memory device. The first transistor includes a channel region, a gate structure surrounding the channel region, and a plurality of source/drain regions on opposite sides of the gate structure. The second transistor is over the first transistor. The second transistor is of a memory cell and includes a gate electrode, a gate dielectric layer, an indium gallium zinc oxide layer, a first titanium nitride source/drain electrode, and a second titanium nitride source/drain electrode. The gate dielectric layer is over the gate electrode. The indium gallium zinc oxide layer is over the gate dielectric layer. The first titanium nitride source/drain electrode is formed on a first side of the indium gallium zinc oxide layer. The second titanium nitride source/drain electrode is formed on a second side of the indium gallium zinc oxide layer opposite to the first side. The first gate contact is over the gate electrode. From a top view, the indium gallium zinc oxide layer encloses the gate contact. In some embodiments, the first transistor is of the sense amplifier, and the semiconductor structure further includes: a second gate contact over the gate structure of the first transistor, the second gate contact overlapping the channel region of the first transistor. In some embodiments, the first transistor is of the power header, and the semiconductor structure further includes: a second gate contact over the gate structure of the first transistor, the second gate contact non-overlapping the channel region of the first transistor. In some embodiments, the first transistor is of a p-type metal-oxide-semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first gate structure across a first active region on a substrate within a memory region, wherein the first gate structure is of a first transistor being of a first conductivity type;
forming a second gate structure across a second active region on the substrate within a peripheral region, wherein the second gate structure is of a second transistor being of a second conductivity type, the second conductivity type is opposite to the first conductivity type;
forming a first gate contact over the first gate structure, the first gate contact overlapping with the first active region; and
forming a second gate contact over the second gate structure, the second gate contact non-overlapping with the second active region.

2. The method of claim 1, wherein the first transistor is of an n-channel metal-oxide-semiconductor transistor.

3. The method of claim 1, wherein from a top view, the first gate contact is laterally spaced apart from an edge of the first active region by a distance at least about 10 nm.

4. The method of claim 1, further comprising:
forming a third gate structure across the first active region within the memory region, the third gate structure is of a third transistor, the third transistor forming an anti-fuse memory cell with the first transistor, the third gate structure electrically connected to a read word line, and the first gate structure electrically connected to a program word line; and
forming a third gate contact over the third gate structure, the third gate contact non-overlapping with the first active region.

5. The method of claim 1, wherein the first transistor is a thin film transistor, the thin film transistor comprising a gate layer, a high-k dielectric layer over the gate layer, an indium gallium zinc oxide layer over the high-k dielectric layer, and a plurality of titanium nitride layers on opposite sides of the indium gallium zinc oxide layer.

6. The method of claim 1, wherein the second transistor is of a p-channel metal-oxide-semiconductor transistor.

7. The method of claim 1, wherein from a top view, the second gate contact is laterally spaced apart from an edge of the second active region by a distance at least about 15 nm.

8. The method of claim 1, wherein the memory region is at a higher position than the peripheral region.

9. The method of claim 1, further comprising:
forming a third gate structure across a third active region within the peripheral region over the substrate, wherein the third gate structure is of a third transistor being of the second conductivity type; and
forming a third gate contact over the third gate structure, the third gate contact overlapping with the third active region.

10. The method of claim 9, wherein the second transistor is of a power header transistor, and the third transistor is of a sense amplifier transistor.

11. A method, comprising:
forming a plurality of fin structures upwardly extending from a semiconductor substrate within a memory bit-cell;
forming a first gate strip extending across the fin structures, and a second gate strip extending across the fin structures;
growing a plurality of source/drain structures on the fin structures;
forming a first gate contact over the first gate strip, wherein from a top view, the first gate contact is positioned within a region bordered by a first outer edge of a first outermost one of the fin structures and a second outer edge of a second outermost one of the fin structures opposite to the first outer edge; and
forming a second gate contact over the second gate strip, wherein from the top view, the second gate contact is positioned outside of the region bordered by the first and second outer edges of the first and second outermost ones of the fin structures.

12. The method of claim 11, wherein the first gate strip is electrically connected to a read word line through the first gate contact, and the second gate strip is electrically connected to a program word line through the second gate contact.

13. The method of claim 11, wherein the first gate strip is of a first n-type metal-oxide-semiconductor (NMOS) device, and the second gate strip is of a second NMOS device.

14. The method of claim 11, wherein from the top view, the second gate contact is spaced apart from the region by a non-zero distance.

15. The method of claim 11, further comprising:
forming a third gate strip extending across the fin structures and between the first and second gate strips; and
forming a third gate contact over the third gate strip, wherein from the top view, the second gate contact is positioned outside of the region bordered by the first and second outer edges of the first and second outermost ones of the fin structures.

16. The method of claim 11, further comprising:
forming a third gate strip extending across the fin structures, wherein the second gate strip is between the first and third gate strips; and
forming a third gate contact over the third gate strip, wherein from the top view, the second gate contact is positioned within the region bordered by the first and second outer edges of the first and second outermost ones of the fin structures.

17. A semiconductor structure, comprising:
a substrate;
a first transistor over the substrate, the first transistor being of a sense amplifier or a power header of a memory device, the first transistor comprising a channel region, a gate structure surrounding the channel region, and a plurality of source/drain regions on opposite sides of the gate structure;
a second transistor over the first transistor, the second transistor being of a memory cell and comprising:
a gate electrode;
a gate dielectric layer over the gate electrode;
an indium gallium zinc oxide layer over the gate dielectric layer;
a first titanium nitride source/drain electrode formed on a first side of the indium gallium zinc oxide layer; and
a second titanium nitride source/drain electrode formed on a second side of the indium gallium zinc oxide layer opposite to the first side; and
a first gate contact over the gate electrode, wherein from a top view, the indium gallium zinc oxide layer encloses the first gate contact.

18. The semiconductor structure of claim 17, wherein the first transistor is of the sense amplifier, and the semiconductor structure further comprises:
a second gate contact over the gate structure of the first transistor, the second gate contact overlapping the channel region of the first transistor.

19. The semiconductor structure of claim 17, wherein the first transistor is of the power header, and the semiconductor structure further comprises:
a second gate contact over the gate structure of the first transistor, the second gate contact non-overlapping the channel region of the first transistor.

20. The semiconductor structure of claim 17, wherein the first transistor is of a p-type metal-oxide-semiconductor device.
